(19) United States
(12) Patent Application Publication
(10) Pub. No.: US 2025/0239408 A1
(43) Pub. Date: Jul. 24, 2025

(54) MULTILAYER CERAMIC CAPACITOR, PACKAGE, AND CIRCUIT BOARD

(71) Applicant: TAIYO YUDEN CO., LTD., Tokyo (JP)

(72) Inventor: Ayumi SHIROTA, Tokyo (JP)

(73) Assignee: TAIYO YUDEN CO., LTD., Tokyo (JP)

(21) Appl. No.: 18/986,134

(22) Filed: Dec. 18, 2024

Related U.S. Application Data
(63) Continuation of application No. PCT/JP2023/023160, filed on Jun. 22, 2023.

(30) Foreign Application Priority Data
Jul. 5, 2022 (JP) 2022-108531

(51) Int. Cl. H01G 4/30; H01G 4/008; H01G 4/012; H05K 1/18

(52) U.S. Cl. CPC H01G 4/30; H01G 4/0085; H01G 4/012; H05K 1/181; H05K 2201/10015

(57) ABSTRACT

A multilayer ceramic capacitor has a dimension in a first direction equal to or greater than 1.5 times a dimension in a second direction, and includes a ceramic body and a pair of external electrodes. The ceramic body further includes a multilayer portion including internal electrodes that are alternately stacked with ceramic layers along a stacking direction parallel to the first or second direction, and a pair of margin portions that cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion. The internal electrodes include inner-side internal electrodes, and outer-side internal electrodes having a maximum width dimension smaller than a minimum width dimension of the inner-side internal electrodes.

### CROSS-REFERENCE TO RELATED APPLICATION

This application is a continuation application of PCT/JP2023/023160 filed on Jun. 22, 2023, which claims priority to Japanese Patent Application No. 2022-108531 filed on Jul. 5, 2022, the entire contents of which are incorporated herein by reference.

### FIELD

A certain aspect of the present disclosure relates to a multilayer ceramic capacitor, a package, and a circuit board.

### BACKGROUND

In recent years, electronic devices such as portable information terminals have been miniaturized, and the mounting area for a multilayer ceramic capacitor on a circuit board has been limited. On the other hand, a further increase in the capacitance of the multilayer ceramic capacitor is desired.

In order to achieve a large capacitance of a multilayer ceramic capacitor, a technique is known in which a green chip having a structure in which internal electrodes are exposed on side surfaces is formed, and ceramic green sheets for side surfaces are attached to the side surfaces to form ceramic protective layers as disclosed in Japanese Patent Application Laid-Open No. 2012-209539 (Patent Document 1). In such a technique, the green chip in which the internal electrodes are stacked is pressure-bonded by means of isostatic pressing or the like, whereas the ceramic protective layer made of the ceramic green sheet is not pressure-bonded. Therefore, after firing, the density of the ceramic protective layer tends to be lower than the density of the fired body (multilayer portion) of the green chip. In addition, the ceramic green sheets for side surfaces may contain a large amount of organic compounds such as a binder in order to improve the adhesion to the green chip. This can further increase the density difference between the ceramic protective layer and the multilayer portion.

In order to solve such a problem, for example, a technique of densifying the ceramic protective layer by adding Mg, Mn, Zr, Ti, Li, Mo, Nb, Cu, a rare earth element, or the like is known as disclosed in Japanese Patent Application Laid-Open No. 2017-038036 (Patent Document 2). Alternatively, there is also a known technique of adding Sn to ceramic green sheets for side surfaces in order to further reduce the thickness of the ceramic protective layer and improve reliability as disclosed in Japanese Patent Application Laid-Open No. 2021-044533 (Patent Document 3).

### SUMMARY

On the other hand, when an element such as Mg, Mn, Zr, Ti, Li, Mo, Nb, Cu, a rare earth element, or Sn is added to the ceramic green sheets for side surfaces, the sinterability of the ceramic protective layers is increased, and the ceramic protective layers are easily shrunk by firing. This causes the end portions of the internal electrodes in contact with the ceramic protective layer to curve inward in the stacking direction, and the end portions of the internal electrodes are likely to come into contact with each other. As a result, the dielectric strength of the multilayer ceramic capacitor may be reduced. Such a decrease in dielectric strangulation resistance due to the curvature of the end portions of the internal electrodes is more significant in a tall structure in which the number of stacked internal electrodes is large.

In view of the circumstances as described above, it is an object of the present disclosure to provide a multilayer ceramic capacitor, a package, and a circuit board that are capable of reducing a decrease in insulation resistance in a tall structure.

A multilayer ceramic capacitor according to an embodiment of the present disclosure has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes cover the pair of end surfaces, respectively.

The ceramic body further includes:
a multilayer portion including a plurality of internal electrodes that are alternately stacked with ceramic layers along a stacking direction parallel to the first axis or the second axis, and are led out to the end surfaces; and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis.

The plurality of internal electrodes include:
a plurality of inner-side internal electrodes located in an inner side in the stacking direction, and
a plurality of outer-side internal electrodes that are located in both outer sides in the stacking direction, and have a maximum width dimension smaller than a minimum width dimension of the inner-side internal electrodes.

A multilayer ceramic capacitor according to another embodiment of the present disclosure has a dimension in a first direction along a first axis equal to or greater than 1.3 times a dimension in a second direction along a second axis orthogonal to the first axis, and is to be mounted on a mounting surface perpendicular the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes cover the pair of end surfaces, respectively.

The ceramic body further includes:
a multilayer portion including a plurality of internal electrodes that are alternately stacked with ceramic layers along a stacking direction parallel to the first axis or the second axis, and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis.

The plurality of internal electrodes include:
a plurality of inner-side internal electrodes located in an inner side in the stacking direction, and
a plurality of outer-side internal electrodes that are located in both outer sides in the stacking direction and have a maximum width dimension smaller than a minimum width dimension of the inner-side internal electrodes.

In the above configuration, the maximum width dimension of the outer-side internal electrode is smaller than the minimum width dimension of the inner-side internal electrode, and thus the end portion of the outer-side internal electrode in the width direction may be separated from the margin portion. Thus, even when the margin portion shrinks in the stacking direction due to the influence of the additive elements during firing, the end portion of the outer-side internal electrode is inhibited from being curved inward in the stacking direction due to the shrinkage of the margin portion. Therefore, short-circuiting at the end portions of the outer-layer internal electrodes is inhibited, and poor insulation of the multilayer ceramic capacitor is inhibited.

For example, the maximum width dimension of the outer-side internal electrodes may be equal to or greater than two times a thickness dimension of each of the margin portions.

For example, the maximum width dimension of the outer-side internal electrodes may be equal to or less than 10 times the thickness dimension of each of the margin portions.

For example, respective distances in the width direction between the end portions in the width direction of the outer-side internal electrodes and the margin portions may be equal to or larger than the thickness dimension of each of the margin portions.

For example, the respective distances in the width direction between the end portions in the width direction of the outer-side internal electrodes and the margin portions may be equal to or less than five times the thickness dimension of each of the margin portion.

For example, the number of the outer-side internal electrodes stacked in one side in the stacking direction may be 5% or greater and 25% or less of the number of all the internal electrodes stacked.

The stacking direction may be parallel to the second axis, and the width direction of the internal electrodes may be parallel to the first axis.

In this configuration, the cross-sectional area of each of the internal electrodes can be made larger than that in the case where the width direction of the internal electrodes is parallel to the second axis. This makes it possible to increase the area of the internal electrode exposed at the end surface, and to inhibit poor connection between the internal electrode and the external electrode.

In this case, the main surfaces may have a higher flatness than the side surfaces.

This can increase the flatness of the main surface opposed to the mounting surface, and can increase the mounting stability of the multilayer ceramic capacitor.

A package according to another embodiment of the present disclosure includes a multilayer ceramic capacitor, a carrier tape, and a top tape.

The multilayer ceramic capacitor has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes cover the pair of end surfaces, respectively.

The ceramic body further includes:
a multilayer portion including a plurality of internal electrodes that are alternately stacked with ceramic layers along a stacking direction parallel to the first axis or the second axis, and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis.

The plurality of internal electrodes include:
a plurality of inner-side internal electrodes located in an inner side in the stacking direction, and
a plurality of outer-side internal electrodes that are located in both outer sides in the stacking direction, and have a maximum width dimension smaller than a minimum width dimension of the inner-side internal electrodes.

The carrier tape has a sealing surface perpendicular to the first axis, and a recess that is recessed from the sealing surface in the first direction and accommodates the multilayer ceramic capacitor.

The top tape is attached to the sealing surface and covers the recess.

A package according to another embodiment of the present disclosure includes a multilayer ceramic capacitor, a carrier tape, and a top tape.

The multilayer ceramic capacitor according to another embodiment of the present disclosure has a dimension in a first direction along a first axis equal to or greater than 1.3 times a dimension in a second direction along a second axis orthogonal to the first axis, and is to be mounted on a mounting surface perpendicular the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes cover the pair of end surfaces, respectively.

The ceramic body further includes:
a multilayer portion including a plurality of internal electrodes that are alternately stacked with ceramic layers along a stacking direction parallel to the first axis or the second axis, and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis.

The plurality of internal electrodes include:
a plurality of inner-side internal electrodes located in an inner side in the stacking direction, and
a plurality of outer-side internal electrodes that are located in both outer sides in the stacking direction and have a maximum width dimension smaller than a minimum width dimension of the inner-side internal electrodes.

The carrier tape has a sealing surface perpendicular to the first axis, and a recess that is recessed from the sealing surface in the first direction and accommodates the multilayer ceramic capacitor.

The top tape is attached to the sealing surface and covers the recess.

A circuit board according to another embodiment of the present disclosure includes a multilayer ceramic capacitor and a mounting substrate.

The multilayer ceramic capacitor has a dimension in a first direction along a first axis equal to or greater than 1.5 times a dimension in a second direction along a second axis orthogonal to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes cover the pair of end surfaces, respectively.

The ceramic body further includes:
a multilayer portion including a plurality of internal electrodes that are alternately stacked with ceramic layers along a stacking direction parallel to the first axis or the second axis, and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis.

The plurality of internal electrodes include:
a plurality of inner-side internal electrodes located in an inner side in the stacking direction, and
a plurality of outer-side internal electrodes that are located in both outer sides in the stacking direction, and have a maximum width dimension smaller than a minimum width dimension of the inner-side internal electrodes.

The mounting substrate has a mounting surface perpendicular to the first axis, and a pair of connection electrodes provided on the mounting surface and connected to the pair of external electrodes of the multilayer ceramic capacitor through solder.

A circuit board according to another embodiment of the present disclosure includes a multilayer ceramic capacitor and a mounting substrate.

The multilayer ceramic capacitor has a dimension in a first direction along a first axis equal to or greater than 1.3 times a dimension in a second direction along a second axis orthogonal to the first axis.

The multilayer ceramic capacitor includes a ceramic body and a pair of external electrodes.

The ceramic body has a pair of main surfaces perpendicular to the first axis, a pair of side surfaces perpendicular to the second axis, and a pair of end surfaces perpendicular to a third axis orthogonal to the first axis and the second axis.

The pair of external electrodes cover the pair of end surfaces, respectively.

The ceramic body further includes:
a multilayer portion including a plurality of internal electrodes that are alternately stacked with ceramic layers along a stacking direction parallel to the first axis or the second axis, and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis.

The plurality of internal electrodes include:
a plurality of inner-side internal electrodes located in an inner side in the stacking direction, and
a plurality of outer-side internal electrodes that are located in both outer sides in the stacking direction and have a maximum width dimension smaller than a minimum width dimension of the inner-side internal electrodes.

The mounting substrate has a mounting surface perpendicular to the first axis, and a pair of connection electrodes provided on the mounting surface and connected to the pair of external electrodes of the multilayer ceramic capacitor through solder.

### BRIEF DESCRIPTION OF THE DRAWINGS

FIG. 1 is a perspective view of a multilayer ceramic capacitor according to a first embodiment;

FIG. 2 is a cross-sectional view of the multilayer ceramic capacitor taken along line A-A′ in FIG. 1;

FIG. 3 is a cross-sectional view of the multilayer ceramic capacitor taken along line B-B′ in FIG. 1;

FIG. 4 is a partially exploded view of a ceramic body of the multilayer ceramic capacitor;

FIG. 5 is a cross-sectional view of a multilayer ceramic capacitor according to a comparative example, and illustrates the same cross section as FIG. 3;

FIG. 6 is a flowchart illustrating a method of manufacturing the multilayer ceramic capacitor;

FIG. 7A and FIG. 7B are plan views of ceramic sheets prepared in step S01;

FIG. 8A and FIG. 8B are plan views of the ceramic sheets prepared in step S01;

FIG. 9 is a plan view of the ceramic sheet prepared in step S01;

FIG. 10 schematically illustrates step S02;

FIG. 11 is a plan view illustrating step S03;

FIG. 12A, FIG. 12B, and FIG. 12C are cross-sectional views illustrating step S03;

FIG. 13A and FIG. 13B are cross-sectional views illustrating step S04;

FIG. 14 is a side view of a circuit board including the multilayer ceramic capacitor;

FIG. 15 is a partial plan view of a package of the multilayer ceramic capacitor;

FIG. 16 is a cross-sectional view of the package taken along line C-C′ in FIG. 15;

FIG. 17 is a cross-sectional view of a multilayer ceramic capacitor in accordance with a second embodiment, taken along line B-B′ in FIG. 1;

FIG. 18 is a cross-sectional view of the multilayer ceramic capacitor taken along line D-D′ in FIG. 1;

FIG. 19 is a partially exploded view of the ceramic body of the multilayer ceramic capacitor;

FIG. 20A and FIG. 20B are plan views of ceramic sheets prepared in step S01 of the method of manufacturing the multilayer ceramic capacitor;

FIG. 21A and FIG. 21B are plan views of ceramic sheets prepared in step S01 of the method of manufacturing the multilayer ceramic capacitor;

FIG. 22 is a plan view of a ceramic sheet prepared in step S01 of the method of manufacturing a multilayer ceramic capacitor;

FIG. 23 schematically illustrates step S02 of the method of manufacturing the multilayer ceramic capacitor; and

FIG. 24A and FIG. 24B are partial cross-sectional views illustrating a method of calculating the flatness of the main surface and the flatness of the side surface of the multilayer ceramic capacitor, FIG. 24A illustrates a cross section of the center of the main surface, and FIG. 24B illustrates a cross section of the center of the side surface.

### DETAILED DESCRIPTION

Hereinafter, a multilayer ceramic capacitor 10 according to an embodiment of the present disclosure will be described with reference to the drawings. In the drawings, an X-axis, a Y-axis, and a Z-axis orthogonal to each other are illustrated as appropriate. The X-axis, the Y-axis, and the Z-axis define a fixed coordinate system fixed with respect to the multilayer ceramic capacitor 10.

### First Embodiment

### [Structure of Multilayer Ceramic Capacitor 10]

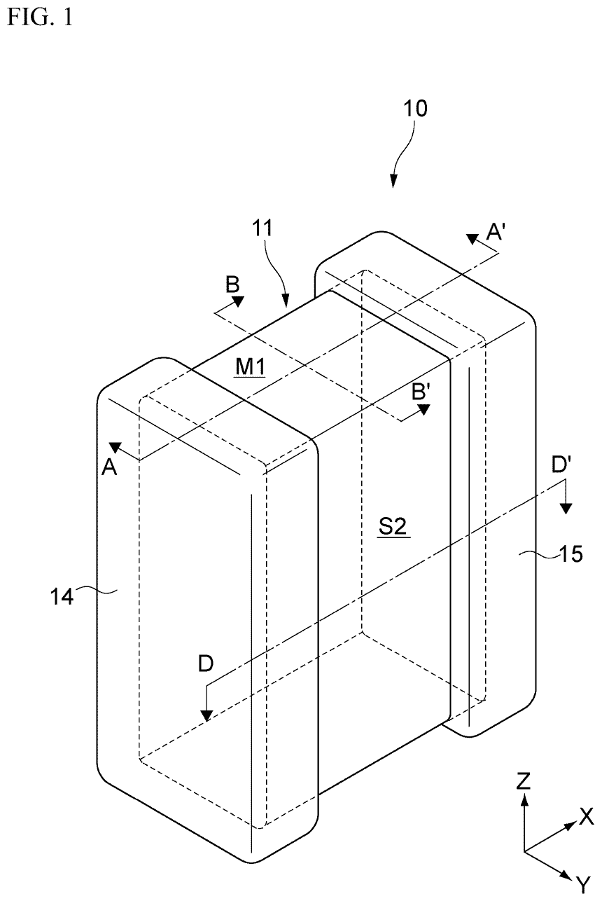

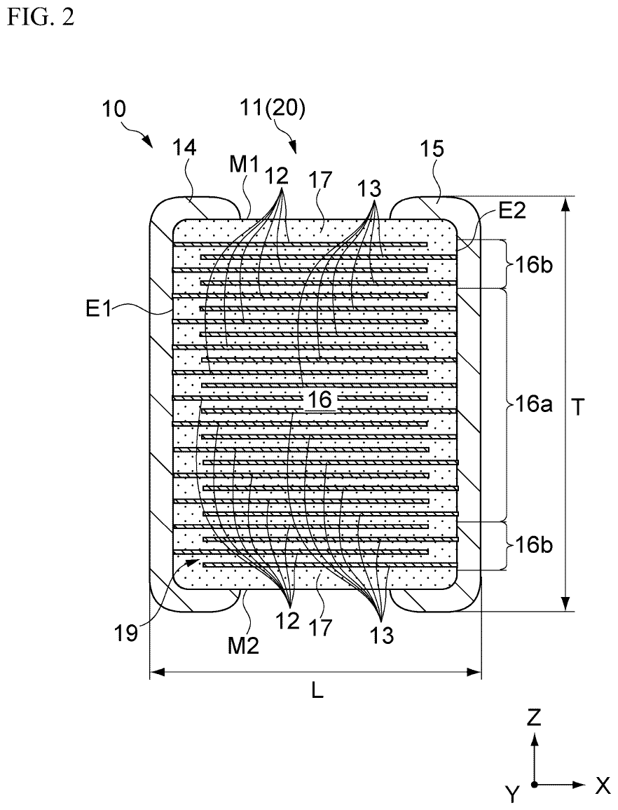

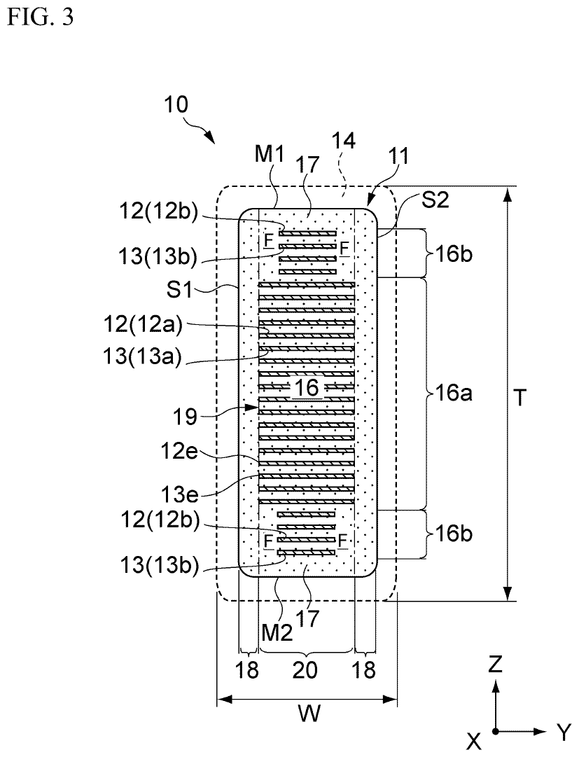

FIG. 1 to FIG. 3 illustrate the multilayer ceramic capacitor 10 according to an embodiment of the present disclosure. FIG. 1 is a perspective view of the multilayer ceramic capacitor 10. FIG. 2 is a cross-sectional view of the multilayer ceramic capacitor 10 taken along line A-A′ in FIG. 1. FIG. 3 is a cross-sectional view of the multilayer ceramic capacitor 10 taken along line B-B′ in FIG. 1.

FIG. 2 and FIG. 3 each illustrates a vertical cross section of a section including the central portion of the multilayer ceramic capacitor 10. Specifically, FIG. 2 illustrates a cross section of the multilayer ceramic capacitor 10 along the X-Z plane at the center in the Y-axis direction. FIG. 3 illustrates a cross section of the multilayer ceramic capacitor 10 taken along the Y-Z plane at the center in the X-axis direction.

The multilayer ceramic capacitor 10 includes a ceramic body 11, a first external electrode 14, and a second external electrode 15. The ceramic body 11 is configured as a hexahedron having first and second main surfaces M1 and M2 orthogonal to the Z-axis, first and second end surfaces E1 and E2 orthogonal to the X-axis, and first and second side surfaces S1 and S2 orthogonal to the Y-axis. The “hexahedron” may be substantially hexahedral, and for example, the ridge portions connecting the surfaces of the ceramic body 11 may be rounded.

The main surfaces M1 and M2, the end surfaces E1 and E2, and the side surfaces S1 and S2 of the ceramic body 11 are all flat surfaces. The flat surface in the present embodiment does not have to be strictly flat as long as it is a surface recognized as flat when viewed as a whole, and includes, for example, a surface having minute surface irregularities, a surface having a gently curved shape in a predetermined area, and the like.

The multilayer ceramic capacitor 10 is a tall type in which the dimension T in the Z-axis direction is equal to or greater than 1.5 times the dimension W in the Y-axis direction. In the multilayer ceramic capacitor 10, the capacitance is increased by increasing the dimension T corresponding to the height. Thus, the multilayer ceramic capacitor 10 can be mounted in a mounting space limited in the Y-axis direction.

The multilayer ceramic capacitor 10 may be a tall type in which the dimension T in the Z-axis direction is equal to or greater than 1.3 times the dimension W in the Y-axis direction.

In the multilayer ceramic capacitor 10, the dimension L in the X-axis direction of the ceramic body 11 may be smaller than the dimension T as long as it is larger than the dimension W. In the multilayer ceramic capacitor 10, the dimensions T, W, and L of the ceramic body 11 can be determined as desired within respective ranges satisfying the above conditions.

Specifically, in the multilayer ceramic capacitor 10, for example, the dimension L can be 0.2 mm or greater and 1.2 mm or less, the dimension W is 0.1 mm or greater and 0.7 mm or less, and the dimension T can be 0.15 mm or greater and 1.0 mm or less. The dimensions T, W, and L are all the maximum dimensions of the multilayer ceramic capacitor 10 in respective directions.

In the following description, “inner side in the Z-axis direction” refers to a side closer to a virtual X-Y plane that bisects the multilayer ceramic capacitor 10 in the Z-axis direction, and “outer side in the Z-axis direction” refers to a side farther from the virtual X-Y plane. Similarly, the “inner side in the Y-axis direction” refers to a side closer to a virtual X-Z plane that bisects the multilayer ceramic capacitor 10 in the Y-axis direction, and the “outer side in the Y-axis direction” refers to a side farther from the virtual X-Z plane.

The external electrodes 14 and 15 cover the end surfaces E1 and E2 of the ceramic body 11, respectively. In the present embodiment, the external electrode 14 extends from the end surface E1 to the main surfaces M1 and M2 and the side surfaces S1 and S2, and the external electrode 15 extends from the end surface E2 to the main surface M1 and M2 and the side surfaces S1 and S2. As a result, in the external electrodes 14 and 15, the cross sections parallel to the X-Z plane and the X-Y plane are both U-shaped. The shape of each of the external electrodes 14 and 15 is not limited to the example illustrated in FIG. 1.

The external electrodes 14 and 15 contain a metal material as a main component. Examples of the metal material constituting the external electrodes 14 and 15 include copper (Cu), nickel (Ni), tin (Sn), palladium (Pd), platinum (Pt), silver (Ag), gold (Au), and alloys thereof. In the present embodiment, the main component refers to a component having the highest content ratio.

The ceramic body 11 includes a multilayer portion 20 and a pair of margin portions 18. The multilayer portion 20 includes a capacitance formation portion 16 and a pair of cover portions 17. The capacitance formation portion 16 includes a plurality of first and second internal electrodes 12 and 13 that are alternately stacked with a plurality of ceramic layers 19 along the Z-axis direction. In the present embodiment, the internal electrodes 12 and 13 and the ceramic layers 19 are each configured in a sheet shape extending along the X-Y plane.

The internal electrodes 12 and 13 are alternately arranged along the Z-axis direction. The internal electrodes 12 and 13 face each other in the Z-axis direction in an opposing section in the center in the X-axis and Y-axis directions. The first internal electrodes 12 are led out from the opposing section to the first end surface E1 and connected to the first external electrode 14. The second internal electrodes 13 are led out from the opposing section to the second end surface E2 and connected to the second external electrode 15.

Here, the direction in which the internal electrodes 12 and 13 are stacked is defined as a “stacking direction”, the direction in which the internal electrodes 12 and 13 are led out is defined as a “lead-out direction”, and the direction orthogonal to the stacking direction and the lead-out direction is defined as a “width direction (of the internal electrodes 12 and 13)”. In the present embodiment, the stacking direction is a direction parallel to the Z-axis, the lead-out direction is a direction parallel to the X-axis, and the width direction is a direction parallel to the Y-axis.

In the present embodiment, the width dimensions in the Y-axis direction (width direction) of the internal electrodes 12 and 13 are different between an inner-side portion 16a and outer-side portions 16b of the capacitance formation portion 16. The detailed configuration will be described later.

The internal electrodes 12 and 13 contain a metal material as a main component. The metal material is, typically, nickel (Ni), but can also be copper (Cu), palladium (Pd), platinum (Pt), silver (Ag), gold (Au), an alloy thereof, and the like.

With such a configuration, in the multilayer ceramic capacitor 10, when a voltage is applied between the external electrodes 14 and 15, the voltage is applied to the ceramic layers 19 between the internal electrodes 12 and 13 in the opposing section. This allows the multilayer ceramic capacitor 10 to store an electric charge corresponding to the voltage between the external electrodes 14 and 15.

In the multilayer portion 20, a dielectric ceramic having a high dielectric constant is used to increase the electrostatic capacitance of each ceramic layer 19 between the internal electrodes 12 and 13. Examples of the dielectric ceramic having a high dielectric constant include a material having a perovskite structure containing barium (Ba) and titanium (Ti), which is represented by barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr, Ti)O₃), barium calcium zirconate titanate ((Ba, Ca)(Zr, Ti)O₃), barium zirconate (BaZrO₃), or titanium dioxide (TiO₂). Furthermore, the multilayer portion 20 may contain additive elements described below in addition to the dielectric ceramic.

The pair of cover portions 17 cover the capacitance formation portion 16 from respective sides in the Z-axis direction, which is the stacking direction. The cover portion 17 is formed of, for example, a layered product of ceramic sheets extending along the X-Y plane. The dielectric ceramic constituting the cover portion 17 preferably has the same composition as the ceramic layer 19 to reduce internal stress.

The pair of margin portions 18 are formed along the Z-axis direction and cover the multilayer portion 20 from the Y-axis direction. The margin portion 18 is attached to a surface of the multilayer portion 20 perpendicular to the Y-axis as described later. For example, the margin portion 18 is formed of a ceramic sheet and is configured in a sheet shape extending along the X-Z plane. The dielectric ceramic constituting the margin portion 18 preferably has the same composition as the ceramic layer 19 to reduce internal stress.

The multilayer portion 20 is integrated by being pressure-bonded from the Z-axis direction, which is the stacking direction, in the manufacturing process. In contrast, the margin portion 18 that is attached later does not undergo the step of pressure-bonding, and thus may have a lower density than the multilayer portion 20. In addition, a large amount of organic compounds such as a binder may be added to the material forming the margin portion 18 in order to increase the adhesion to the multilayer portion 20. This reduces the content ratio of the dielectric ceramic in the material, and thus the denseness of the margin portion 18 after firing may be further reduced. When the denseness of the margin portion 18 is low, the moisture resistance, impact resistance, and crack resistance degrade, and the reliability of the multilayer ceramic capacitor 10 may be decreased.

Therefore, the margin portion 18 contains an additive element composed of at least one of the following elements: magnesium (Mg), manganese (Mn), zirconium (Zr), titanium (Ti), lithium (Li), molybdenum (Mo), niobium (Nb), copper (Cu), a rare earth element, and tin (Sn) at a higher concentration than the multilayer portion 20. That is, the concentration of the additive element in the margin portion 18 is higher than the concentration of the additive element in the ceramic layer 19 and the cover portion 17. Examples of the rare earth element include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), yttrium (Y), erbium (Er), thulium (Tm), ytterbium (Yb), lutetium (Lu), and scandium (Sc). The additive element contained in the margin portion 18 may be one element selected from Mg, Mn, Zr, Ti, Li, Mo, Nb, Cu, a rare earth element, and Sn, or may contain a plurality of elements selected from these elements. The concentration of the additive element refers to the total concentration of the additive elements.

By adding a large amount of Mg, Mn, Zr, Ti, Li, Mo, Nb, Cu, a rare earth element, or Sn to the margin portion 18, sintering of the margin portion 18 can be promoted, and the margin portion 18 can be densified. This can increase the denseness of the margin portion 18 and increase the moisture resistance, impact resistance, and crack resistance of the margin portion 18.

On the other hand, in a general tall-type multilayer ceramic capacitor in which all the internal electrodes have substantially the same width dimension in the Y-axis direction, when a larger amount of an additional element is added to the margin portion than to the multilayer portion, poor insulation may occur. Hereinafter, a multilayer ceramic capacitor 10A according to a comparative example with respect to the present embodiment will be described as an example.

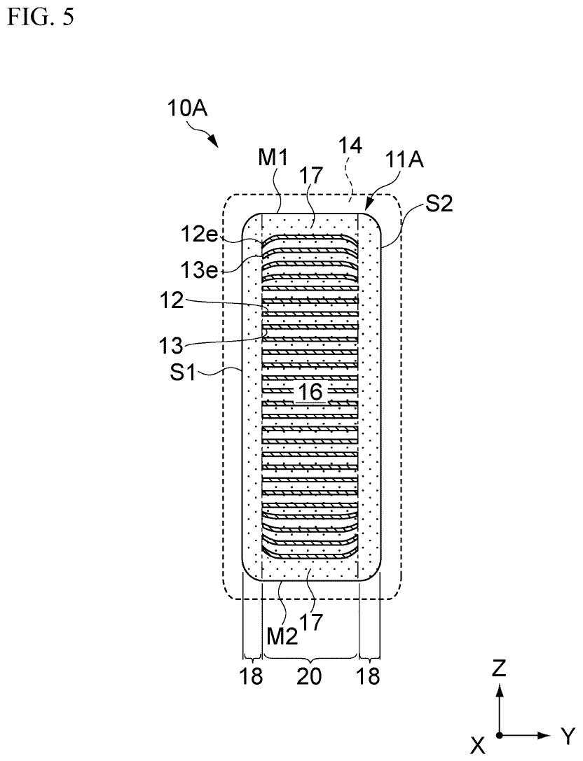

FIG. 5 is a vertical cross-sectional view illustrating the tall multilayer ceramic capacitor 10A according to a comparative example with respect to the present embodiment. In the multilayer ceramic capacitor 10A, all the internal electrodes 12 and 13 have substantially the same width dimensions in the Y-axis direction. The composition of each portion of a ceramic body 11A of the multilayer ceramic capacitor 10A is equivalent to that of the multilayer ceramic capacitor 10 of the present embodiment.

In this multilayer ceramic capacitor 10A, the sintering of the margin portion 18 is promoted during firing due to the influence of the additive elements, and the margin portion 18 may shrink in the Z-axis direction relative to the multilayer portion 20. Therefore, respective end portions 12e and 13e in the Y-axis direction of the internal electrodes 12 and 13 are easily curved inward in the Z-axis direction as the margin portions 18 shrink. Furthermore, since the margin portions 18 shrink from the outer sides toward the center in the Z-axis direction, the curvature of the end portions 12e and 13e of the internal electrodes 12 and 13 may increase at the distances closer to the outer side in the Z-axis direction.

In addition, in the tall ceramic body 11A in which the number of stacked internal electrodes 12 and 13 is large, the amount of shrinkage of the margin portions 18 relative to the multilayer portion 20 is increased, and the curvature of the end portions 12e and 13e of the internal electrodes 12 and 13 in the outer sides in the Z-axis direction may be increased. The curved end portions 12e and 13e of the internal electrodes 12 and 13 reduce the distances between the end portions 12e and 13e of the internal electrodes 12 and 13 adjacent to each other in the Z-axis direction, and which can easily cause poor insulation.

In contrast, in the present embodiment, as illustrated in FIG. 3, the width dimensions of the internal electrodes 12 and 13 in the outer-side portion 16b of the capacitance formation portion 16 are reduced in order to suppress the poor insulation due to the curvature of the end portions 12e and 13e of the internal electrodes 12 and 13. Hereinafter, a detailed configuration of the capacitance formation portion 16 will be described.

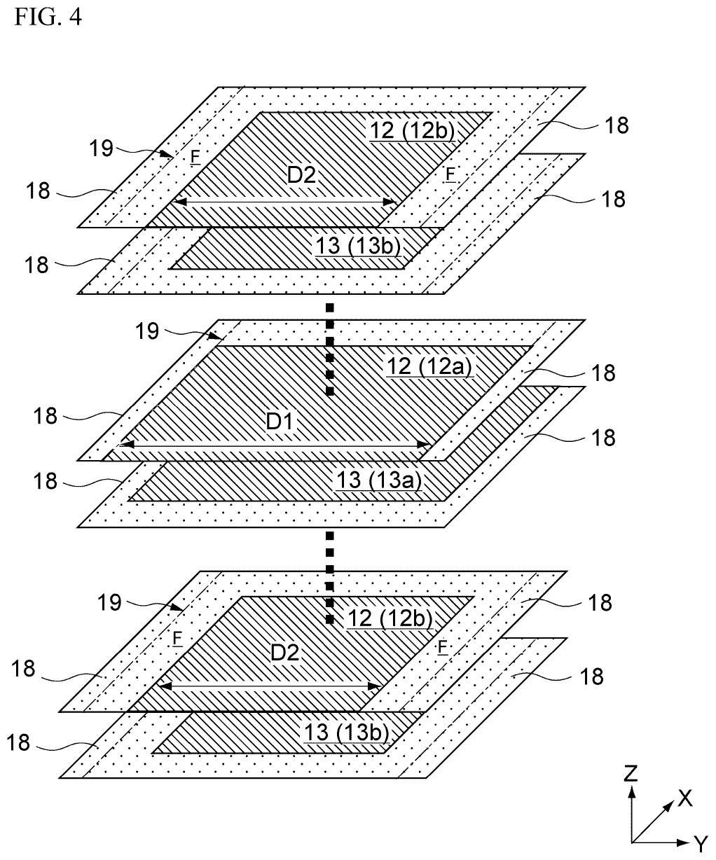

FIG. 4 illustrates the ceramic layers 19, one by one, on which the internal electrodes 12 and 13 are formed, respectively. FIG. 4 also illustrates the margin portions 18 adjacent to the ceramic layer 19.

As illustrated in FIG. 3 and FIG. 4, the first and second internal electrodes 12 and 13 include first and second inner-side internal electrodes 12a and 13a located in the inner side in the Z-axis direction and first and second outer-side internal electrodes 12b and 13b located in both outer sides in the Z-axis direction. In the internal electrodes 12 and 13, the shapes of the inner-side internal electrodes 12a and 13a are different from the shapes of the outer-side internal electrodes 12b and 13b.

As illustrated in FIG. 3, the capacitance formation portion 16 of the present embodiment is divided into the inner-side portion 16a, which is located in the inner side in the Z-axis direction, and a pair of the outer-side portions 16b, which are located in both outer sides in the Z-axis direction. The inner-side internal electrodes 12a and 13a are stacked in the inner-side portion 16a, and the outer-side internal electrodes 12b and 13b are stacked in each of the outer-side portions 16b. That is, in the capacitance formation portion 16, the pair of the outer-side portions 16b are adjacent to the pair of cover portions 17, and the inner-side portion 16a is located between the pair of the outer-side portions 16b.

In the example illustrated in FIG. 4, the inner-side internal electrodes 12a and 13a have a mutually common planar shape. That is, the first and second inner-side internal electrodes 12a and 13a illustrated in FIG. 4 have a mutually inverted positional relationship with respect to the center line that passes through the center in the X-axis direction of the ceramic layer and is parallel to the Y-axis. In the example illustrated in FIG. 4, the inner-side internal electrodes 12a and 13a are formed in a rectangular shape, and the width dimensions thereof in the Y-axis direction are substantially constant along the X-axis direction.

In the example illustrated in FIG. 4, the outer-side internal electrodes 12b and 13b have a mutually common planar shape. That is, the first outer-side internal electrode 12b and the second outer-side internal electrode 13b illustrated in FIG. 4 have a mutually inverted positional relationship with respect to the center line that passes through the center in the X-axis direction of the ceramic layer 19 and is parallel to the Y-axis. In the example illustrated in FIG. 4, the outer-side internal electrodes 12b and 13b are formed in a rectangular shape, and the width dimensions thereof in the Y-axis direction are substantially constant along the X-axis direction.

As illustrated in FIG. 4, the outer-side internal electrodes 12b and 13b have maximum width dimensions D1 smaller than minimum width dimensions D2 of the inner-side internal electrodes 12a and 13a. The minimum width dimensions D1 of the inner-side internal electrodes 12a and 13a are the smallest width dimensions of the inner-side internal electrodes 12a and 13a among the width dimensions along the Y-axis direction, which is the width direction. The maximum width dimensions D2 of the outer-side internal electrodes 12b and 13b are the smallest width dimensions of the outer-side internal electrodes 12b and 13b among the width dimensions along the Y-axis direction, which is the width direction.

As illustrated in FIG. 3 and FIG. 4, the maximum width dimensions D2 of the outer-side internal electrodes 12b and 13b are smaller than the minimum width dimensions D1 of the inner-side internal electrodes 12a and 13a, whereby the end portions 12e and 13e of the outer-side internal electrodes 12b and 13b can be separated from the margin portions 18. Electrode absence sections F of the capacitance formation portion 16 are disposed between the end portions 12e of the outer-side internal electrodes 12b and the margin portions 18 and between the end portions 13e of the outer-side internal electrodes 13b and the margin portions 18. The electrode absence section F is composed of a multilayer body of the ceramic layers 19 or a multilayer body of the ceramic layers 19 and dielectric layers having a composition equivalent to that of the ceramic layer 19.

Since the concentration of the additive element in the electrode absence section F is lower than the concentration of the additive element in the margin portion 18, the amount of shrinkage of the electrode absence section F in the Z-axis direction due to firing is smaller than that of the margin portion 18. Therefore, the end portions 12e and 13e of the outer-side internal electrodes 12b and 13b in contact with the electrode absence sections F are less likely to be curved inward in the Z-axis direction. As a result, short-circuiting between the adjacent outer-side internal electrodes 12b and 13b is suppressed, and poor insulation of the multilayer ceramic capacitor 10 is suppressed.

As described above, according to the multilayer ceramic capacitor 10 of the present embodiment, even when the margin portions 18 shrink due to the influence of the additive element, the end portions 12e and 13e of the outer-side internal electrodes 12b and 13b are inhibited from being curved inward in the Z-axis direction, and thus, the poor insulation is suppressed. Therefore, in the tall multilayer ceramic capacitor 10 capable of achieving a large capacitance with a small mounting area, the reliability of the multilayer ceramic capacitor 10 can be improved.

Furthermore, in order to more reliably inhibit the end portions 12e and 13e of the outer-side internal electrodes 12b and 13b from being curved, the end portions 12e and 13e of the outer-side internal electrodes 12b and 13b are preferably sufficiently spaced apart from the margin portions 18. From this point of view, the respective distances between each of the end portions 12e and 13e of the outer-side internal electrodes 12b and 13b and the margin portions 18 in the width direction (Y-axis direction) are preferably equal to or larger than the thickness dimensions of the margin portions 18, and more preferably equal to or greater than 1.5 times the thickness dimensions of the margin portions 18. The thickness dimension of the margin portion 18 is defined to be the maximum dimension in the width direction (Y-axis direction) of the margin portion 18 covering the inner-side portion 16a.

On the other hand, to increase the effective areas of the outer-side internal electrodes 12b and 13b by ensuring the maximum width dimensions D2 of the outer-side internal electrodes 12b and 13b, the respective distances in the width direction (Y-axis direction) between each of the end portions 12e and 13e of the outer-side internal electrodes 12b and 13b and the margin portions 18 are preferably equal to or less than five times, more preferably equal to or less than three times the thickness dimensions of the margin portions 18 covering the inner-side portion 16a.

Similarly, to increase the effective areas of the outer-side internal electrodes 12b and 13b, the maximum width dimensions D2 of the outer-side internal electrodes 12b and 13b are preferably equal to or greater than two times the thickness dimensions in the width direction (Y-axis direction) of the margin portions 18 covering the inner-side portion 16a.

To ensure sufficient distances between the margin portions 18 and each of the end portions 12e and 13e of the outer-side internal electrodes 12b and 13b, the maximum width dimension D2 is preferably equal to or less than 10 times the thickness dimension of the margin portion 18 covering the inner-side portion 16a.

To more effectively inhibit poor insulation of the multilayer ceramic capacitor 10, the number of the outer-side internal electrodes 12b and 13b stacked in one side in the Z-axis direction, i.e., one outer-side portion 16b is equal to or greater than 5% of, more preferably equal to or greater than 10% of the number of all the internal electrodes 12 and 13 stacked.

To ensure the electrostatic capacitance of the ceramic body 11, the number of the outer-side internal electrodes 12b and 13b stacked in one outer-side portion 16b is preferably equal to or less than 25% of, more preferably equal to or less than 20% of the number of all the internal electrodes 12 and 13 stacked.

### [Method of Manufacturing Multilayer Ceramic Capacitor 10]

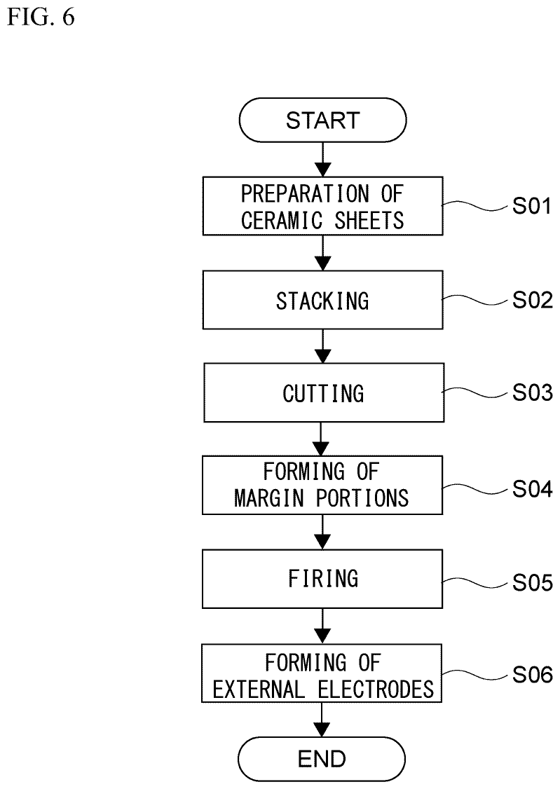

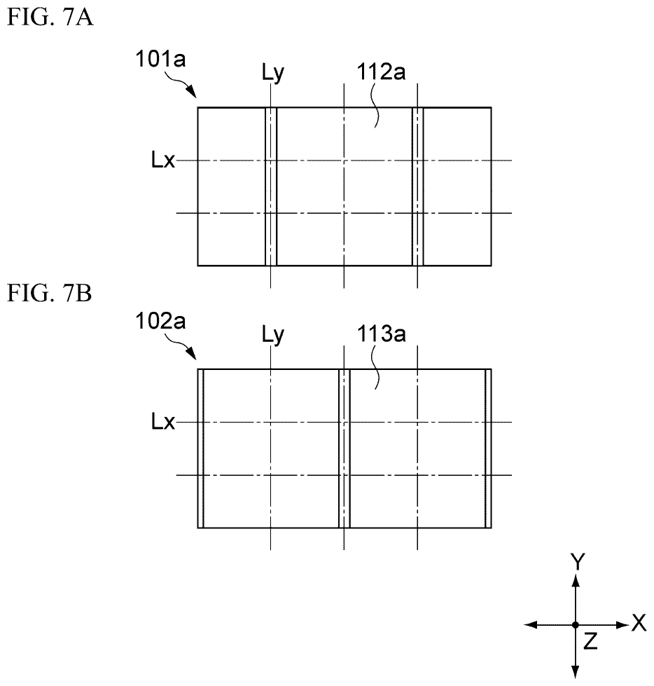

FIG. 6 is a flowchart illustrating a method of manufacturing the multilayer ceramic capacitor 10 according to the present embodiment. FIG. 7A to FIG. 13 illustrate a manufacturing process of the multilayer ceramic capacitor 10. Hereinafter, a method of manufacturing the multilayer ceramic capacitor 10 will be described with reference to these drawings as appropriate.

### (Step S01: Preparation of Ceramic Sheets)

In step S01, prepared are first and second inner-side ceramic sheets 101a and 102a for forming the inner-side portion 16a of the capacitance formation portion 16, first and second outer-side ceramic sheets 101b and 102b for forming a pair of the outer-side portions 16b of the capacitance formation portion 16, and cover ceramic sheets 103 for forming the cover portions 17.

The ceramic sheets 101a, 102a, 101b, 102b, and 103 are each formed as unfired dielectric green sheets containing a dielectric ceramic as a main component. The material of the ceramic sheet includes, for example, ceramic powder, organic compounds such as a binder and an organic solvent, and other additives. The ceramic sheet may contain the above-described additive element. The ceramic sheets 101a, 102a, 101b, 102b, and 103 are formed into a sheet shape by using, for example, a roll coater or a doctor-blade.

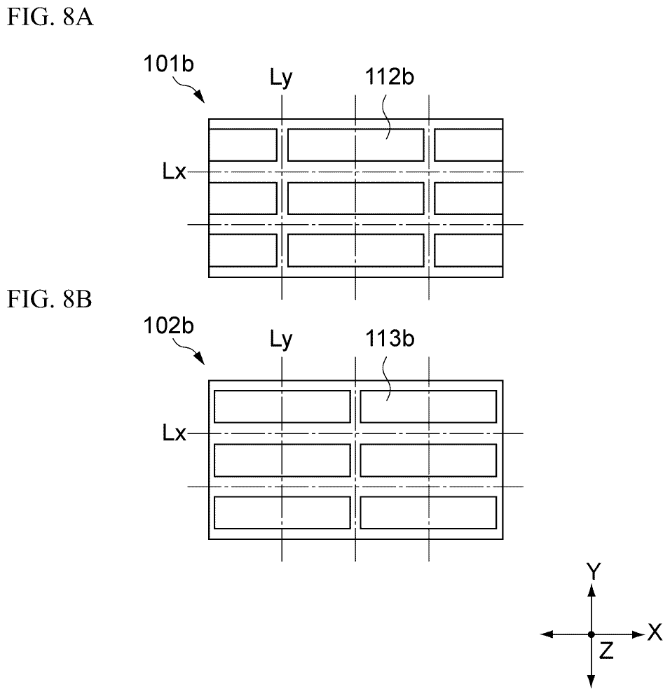

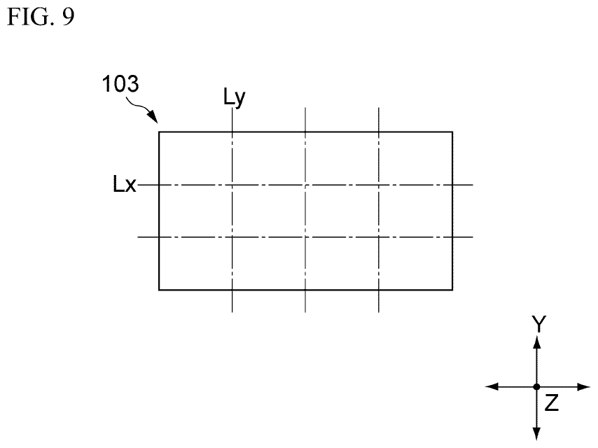

FIG. 7A is a plan view of the first inner-side ceramic sheet 101a. FIG. 7B is a plan view of the second inner-side ceramic sheet 102a. FIG. 8A is a plan view of the first outer-side ceramic sheet 101b. FIG. 8B is a plan view of the second outer-side ceramic sheet 102b. FIG. 9 is a plan view of the cover ceramic sheet 103.

In this stage, the ceramic sheets 101a, 102a, 101b, 102b, and 103 are formed as large-sized sheets that have not been separated into individual pieces. In FIG. 7A to FIG. 9, as cut lines for separating the multilayer ceramic capacitors 10 into individual pieces, first cut lines Lx parallel to the X-axis and second cut lines Ly parallel to the Y-axis are indicated by dash-dotted lines.

Unfired conductor patterns 112a and 113a corresponding to the inner-side internal electrodes 12a and 13a are formed on the inner-side ceramic sheets 101a and 102a, respectively. Unfired conductor patterns 112b and 113b corresponding to the outer-side internal electrodes 12b and 13b are formed on the outer ceramic sheets 101b and 102b, respectively. No unfired conductor pattern is formed on the cover ceramic sheets 103 corresponding to the cover portions 17 where no internal electrodes are provided.

The conductor patterns 112a, 113a, 112b, and 113b are formed by applying a conductive paste to the ceramic sheets 101a, 102a, 101b, and 102b, respectively. The method of applying the conductive paste can be freely selected from known techniques, and for example, a screen printing method or a gravure printing method can be used.

In each of the conductor patterns 112a and 112b and the conductor patterns 113a and 113b, spaces that are along the cut lines Ly and have a width in the X-axis direction are formed every other cut line Ly. The spaces of the conductor pattern 112a and the spaces of the conductor pattern 112b are alternately arranged along the X-axis direction, and the spaces of the conductor pattern 113a and the spaces of the conductor pattern 113b are alternately arranged along the X-axis direction.

Each of the conductor patterns 112a and 113a are continuously formed in the Y-axis direction and are formed in a band shape along the Y-axis direction. On the other hand, in each of the conductor patterns 112b and 113b, spaces that are along the cut lines Lx and have a width in the Y-axis direction are formed. The spaces in the Y-axis direction form the electrode absence sections F.

### (Step S02: Stacking)

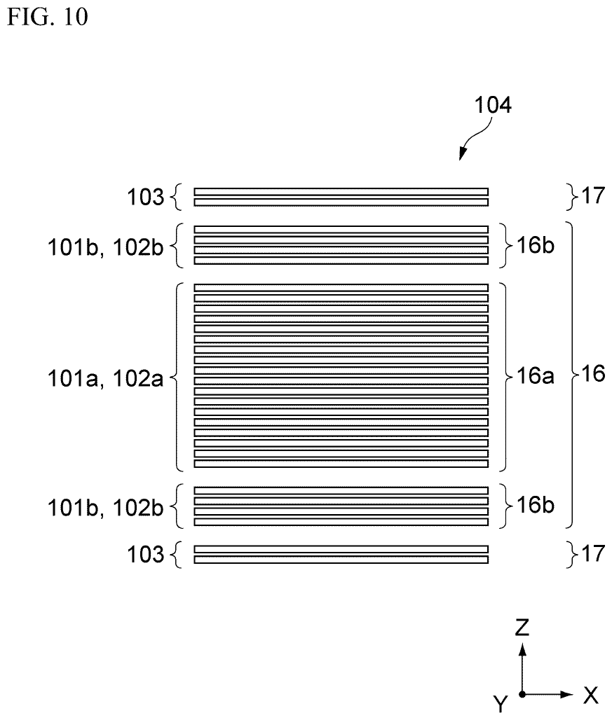

In step S02, the ceramic sheets 101a, 102a, 101b, 102b, and 103 prepared in step S01 are stacked as illustrated in FIG. 10 to produce a multilayer sheet 104. The multilayer sheet 104 is obtained by integrating the stacked ceramic sheets 101a, 102a, 101b, 102b, and 103 by hydrostatic pressurization, uniaxial pressurization, or the like.

In the multilayer sheet 104, the inner-side ceramic sheets 101a and 102a are alternately stacked in the Z-axis direction in the position corresponding to the inner-side portion 16a of the capacitance formation portion 16. In the multilayer sheet 104, the outer-side ceramic sheets 101b and 102b are alternately stacked in the Z-axis direction in positions corresponding to the outer-side portions 16b of the capacitance formation portion 16.

In the multilayer sheet 104, the cover ceramic sheets 103 corresponding to the cover portions 17 are stacked on both upper and lower sides in the Z-axis direction of the ceramic sheets 101a, 102a, 101b, and 102b that have been stacked in the position corresponding to the capacitance formation portion 16. The cover ceramic sheets 103 are continuously stacked in the number corresponding to the thickness of the cover portion 17.

### (Step S03: Cutting)

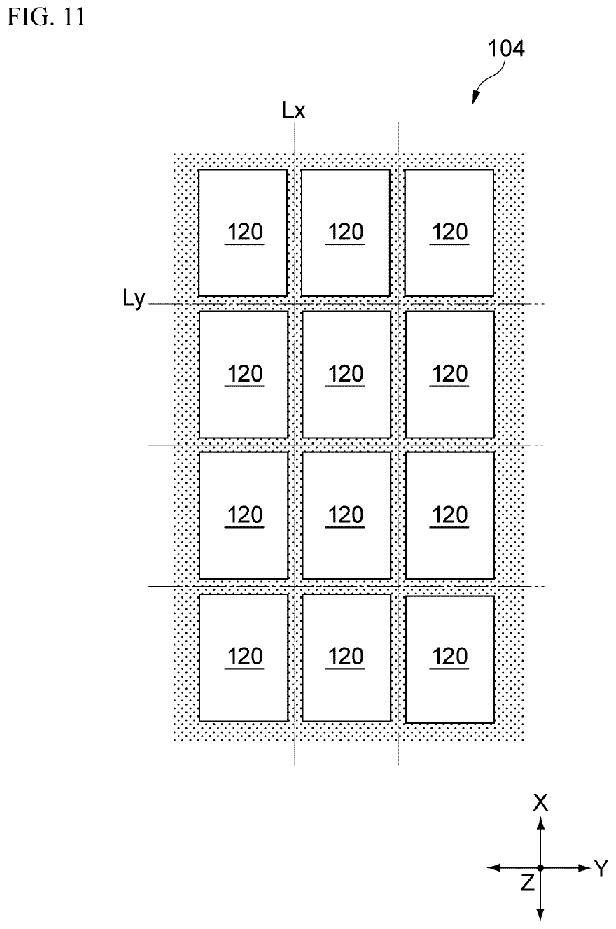

In step S03, the multilayer sheet 104 obtained in step S02 is cut along the cut lines Lx and Ly as illustrated in FIG. 11, thereby obtaining unfired multilayer chips 120 corresponding to the multilayer portions 20. For example, a cutting device provided with a push-cutting blade or a dicing device provided with a rotary blade can be used to cut the multilayer sheet 104 in step S03.

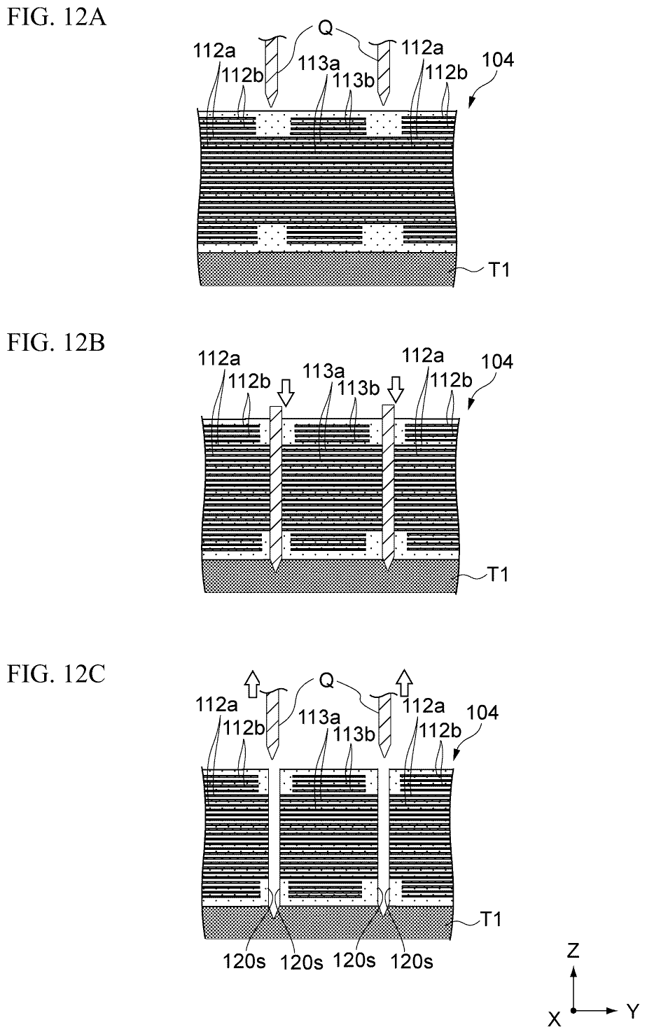

FIG. 12A, FIG. 12B, and FIG. 12C are schematic cross-sectional views illustrating an example of step S03. In FIG. 12A, FIG. 12B, and FIG. 12C, an example of cutting the multilayer sheet 104 using cutting blades Q, which are push-cutting blades, is illustrated.

First, as illustrated in FIG. 12A, the cutting blades Q directed downward in the Z-axis direction are placed above the multilayer sheet 104 in the Z-axis direction. The lower surface of the multilayer sheet 104 in the Z-axis direction is attached to a tape T1.

Then, as illustrated in FIG. 12B, the multilayer sheet 104 is cut by moving the cutting blades Q downward in the Z-axis direction until the cutting blades Q reach the tape T1. At this time, the conductor patterns 112a and 113a corresponding to the inner-side internal electrodes 12a and 13a are cut by the cutting blades Q. On the other hand, the conductor patterns 112b and 113b are not cut by the cutting blades Q because the cutting blades Q pass through the spaces between the conductor patterns 112b and 113b corresponding to the outer-side internal electrodes 12b and 13b.

Then, as illustrated in FIG. 12C, the cutting blades Q are moved upward in the Z-axis direction and pulled out from the multilayer sheet 104.

Thus, the multilayer sheet 104 is separated into a plurality of multilayer chips 120. The multilayer chip 120 has cut surfaces 120s substantially perpendicular to the Y-axis direction and cut surfaces substantially perpendicular to the X-axis direction. As illustrated in FIG. 12C, the conductor patterns 112a and 113a corresponding to the inner-side internal electrodes 12a and 13a are exposed from the cut surfaces 120s of the multilayer chip 120. On the other hand, the conductor patterns 112b and 113b corresponding to the outer-side internal electrodes 12b and 13b are not exposed from the cut surfaces 120s.

Thus, in this step, the conductor patterns 112b and 113b corresponding to the outer-side internal electrodes 12b and 13b are not cut by the cutting blades Q. This inhibits the conductor patterns 112b and 113b from being deformed by large stresses from the cutting blades Q in the vicinity of the upper surface of the multilayer sheet 104 in the Z-axis direction into which the cutting blades Q are inserted. Therefore, this also effectively suppresses the curvature of the end portions 12e and 13e of the outer-side internal electrodes 12b and 12b after being fired and poor insulation associated therewith.

### (Step S04: Forming of Margin Portions)

In step S04, the unfired margin portions 118 are formed on the respective cut surfaces 120s of the multilayer chip 120 obtained in step S03. Through this process, the unfired ceramic body 11 is produced.

The margin portion 118 is formed by, for example, attaching a ceramic sheet or applying a ceramic slurry. The material of the margin portion 118 contains, for example, ceramic powder, the above-described additive element, organic compounds such as a binder and an organic solvent, and other additives. The additive element is added to the margin portion 118 so that the margin portion 118 has a higher concentration of the additive element than the ceramic sheets 101a, 102a, 101b, 102b, and 103 forming the multilayer chip 120.

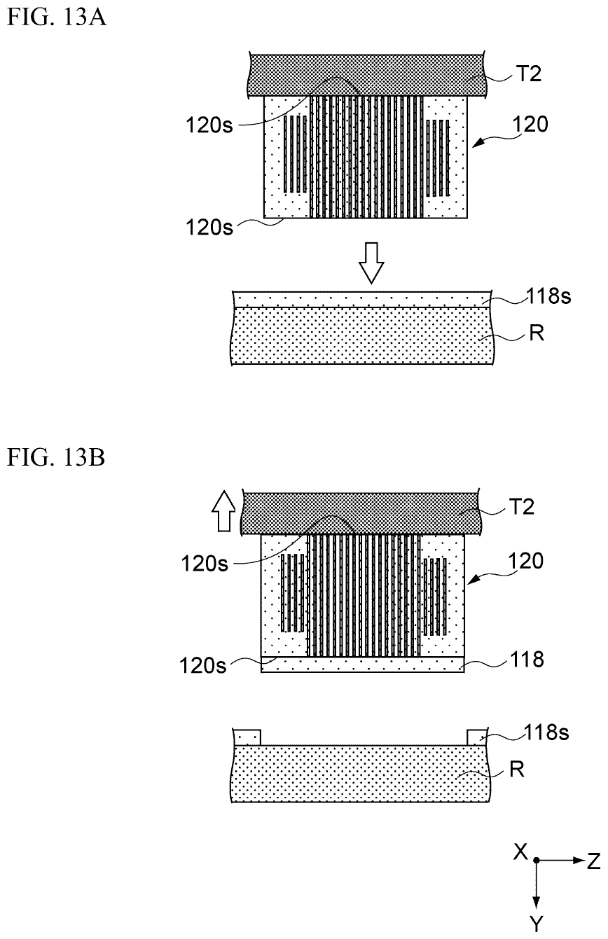

To form the margin portion 18 to have a uniform and small thickness, the margin portion 18 is preferably formed of a ceramic sheet. The following description will be made with reference to FIG. 13A and FIG. 13B.

As illustrated in FIG. 13A, first, one cut surface 120s of the multilayer chip 120 and a ceramic sheet 118s are opposed to each other. The ceramic sheet 118s is disposed on an elastic body R. The multilayer chip 120 is held by a tape T2 at the other cut surface 120s.

Then, as illustrated in FIG. 13A and FIG. 13B, the multilayer chip 120 is pressed against the ceramic sheet 118s in the Y-axis direction, and the ceramic sheet 118s is punched by the cut surface 120s. As a result, the ceramic sheet 118s punched along the peripheral edge of the cut surface 120s is attached to the cut surface 120s, and the unfired margin portion 118 is formed on the cut surface 120s.

Similarly, the ceramic sheet 118s is punched out on the other cut surface 120s of the multilayer chip 120, and the unfired margin portion 118 is formed on the other cut surface 120s. Through this process, the unfired ceramic body 11 including the multilayer chip 120 and a pair of the margin portions 18 is formed.

### (Step S05: Firing)

In step S05, the ceramic body 11 obtained in step S04 is fired. The firing temperature in step S05 can be set to about 1000 to 1300° C., for example, when a barium titanate (BaTiO₃)-based material is used. The firing can be performed, for example, in a reducing atmosphere or a low oxygen partial pressure atmosphere.

In this step, the margin portion 18 may shrink in the Z-axis direction with respect to the multilayer chip 120 due to the influence of the additive element. However, in the present embodiment, the outer-side internal electrodes 12b and 13b are not in contact with the margin portion 18, and therefore, the end portions 12e and 13e of the outer-side internal electrodes 12b and 13b can be inhibited from being curved in the Z-axis direction.

### (Step S06: Forming of External Electrodes)

In step S06, the multilayer ceramic capacitor 10 illustrated in FIG. 1 to FIG. 3 is produced by forming the external electrodes 14 and 15 on respective end portions in the X-axis direction of the ceramic body 11 obtained in step S05. The external electrodes 14 and 15 are formed by applying a conductive paste to the ceramic body 11 and firing the conductive paste.

### [Mounting of Multilayer Ceramic Capacitor 10]

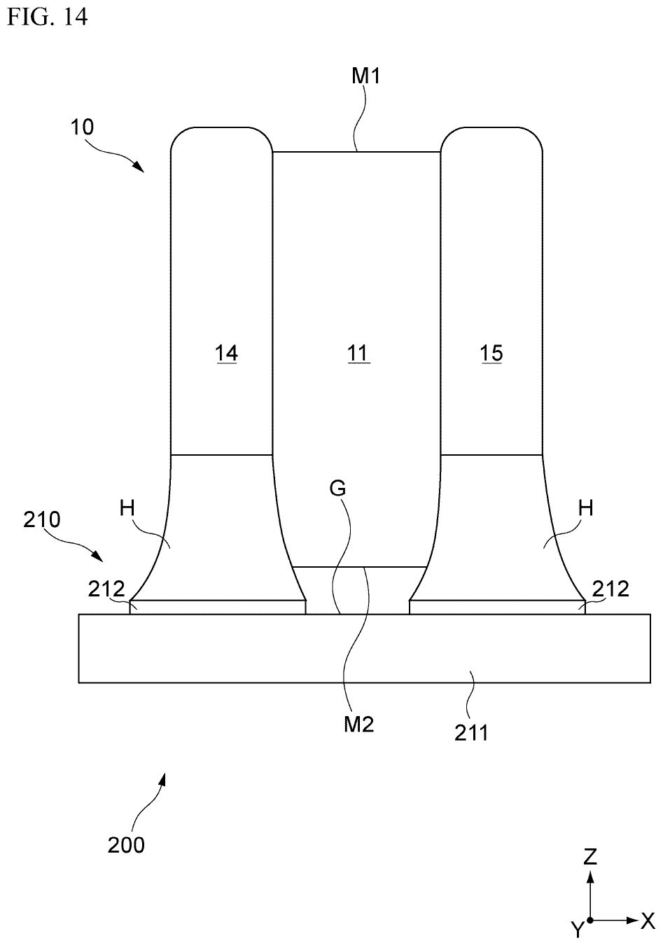

FIG. 14 is a side view of a circuit board 200 including the multilayer ceramic capacitor 10 according to the present embodiment. The circuit board 200 includes a mounting substrate 210 on which the multilayer ceramic capacitor 10 is mounted. The mounting substrate 210 includes a base material 211, which extends along the X-Y plane and has a mounting surface G perpendicular to the Z-axis, and a pair of connection electrodes 212 provided on the mounting surface G.

In the circuit board 200, the external electrodes 14 and 15 of the multilayer ceramic capacitor 10 are connected to the pair of connection electrodes 212 of the mounting substrate 210, respectively, with the solder H interposed therebetween. As a result, in the circuit board 200, the multilayer ceramic capacitor 10 is fixed to and electrically connected to the mounting substrate 210.

Here, in the multilayer ceramic capacitor 10, it is known that, when a voltage is applied to the external electrodes 14 and 15 through the connection electrodes 212 of the mounting substrate 210 at the time of driving the circuit board 200, electrostriction occurs in the ceramic body 11 due to the piezoelectric effect. The electrostriction generated in the ceramic body 11 causes relatively large deformation in the stacking direction of the internal electrodes 12 and 13.

In the circuit board 200, repeated electrostriction in the multilayer ceramic capacitor 10 to which an AC voltage is applied may cause vibration in the thickness direction in the base material 211 of the mounting substrate 210. In the circuit board 200, when the vibration generated in the base material 211 increases, a phenomenon called “sound emission” in which noise sound is emitted from the base material 211 may occur.

In this regard, in the multilayer ceramic capacitor 10 according to the present embodiment, the electrode absence sections F are present on the outer sides of the outer-side internal electrodes 12b and 13b in the Y-axis direction. Since the piezoelectric effect is not generated in the electrode absence section F, the amount of deformation of the ceramic body 11 due to the electrostriction is suppressed in the multilayer ceramic capacitor 10. Therefore, in the present embodiment, it is possible to inhibit sound emission in the circuit board 200.

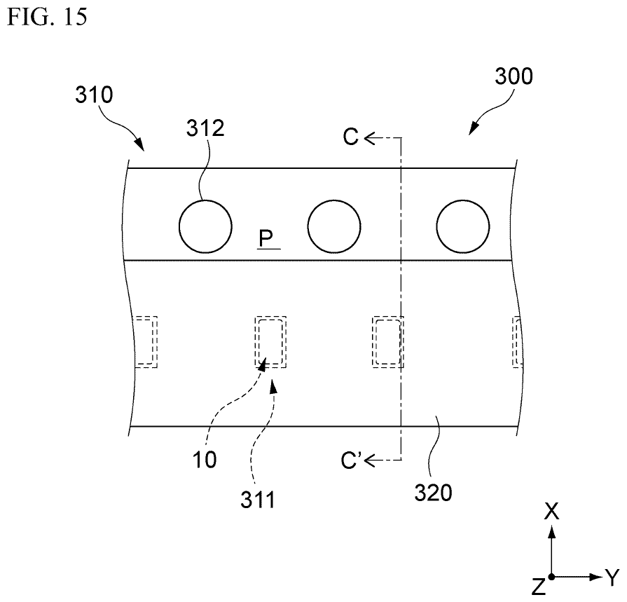

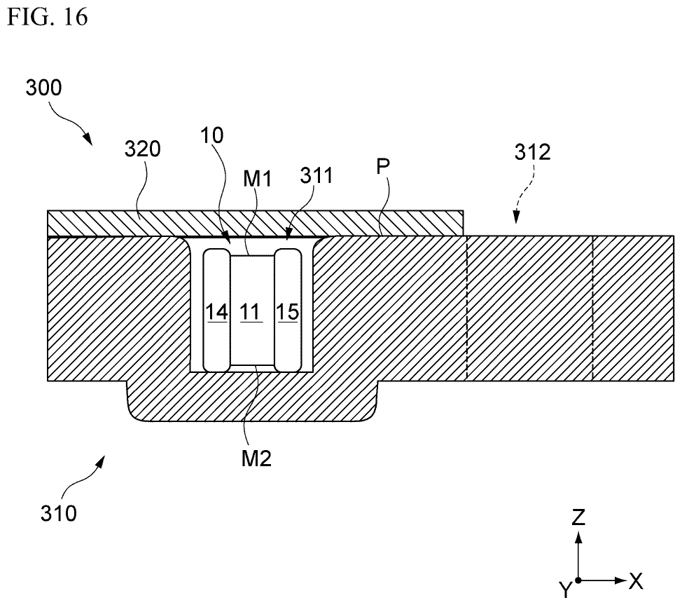

The multilayer ceramic capacitor 10 is prepared in a state of being packaged as a package 300 when being mounted on the mounting substrate 210. FIG. 15 and FIG. 16 illustrate the package 300. FIG. 15 is a partial plan view of the package 300. FIG. 16 is a cross-sectional view of the package 300 taken along line C-C′ in FIG. 15.

The package 300 includes the multilayer ceramic capacitor 10, a carrier tape 310, and a top tape 320. The carrier tape 310 is configured as a long tape extending in the Y-axis direction. In the carrier tape 310, a plurality of recesses 311 each accommodating one multilayer ceramic capacitor 10 are arranged at intervals in the Y-axis direction.

The carrier tape 310 has a sealing surface P that is an upward surface orthogonal to the Z-axis, and the plurality of recesses 311 are recessed downward in the Z-axis direction from the sealing surface P. That is, the carrier tape 310 is configured so that the multilayer ceramic capacitors 10 in the plurality of recesses 311 can be taken out from the sealing surface P side.

In the carrier tape 310, a plurality of feed holes 312 penetrating through the carrier tape 310 in the Z-axis direction and arranged at intervals in the Y-axis direction are provided at positions shifted in the X-axis direction from the row of the plurality of recesses 311. The feed holes 312 are configured as engagement holes used for the tape transport mechanism to transport the carrier tape 310 in the Y-axis direction.

In the package 300, the top tape 320 is attached to the sealing surface P of the carrier tape 310 along the row of the plurality of recesses 311, and the plurality of recesses 311 accommodating the plurality of multilayer ceramic capacitors 10 are collectively covered with the top tape 320. Thus, the multilayer ceramic capacitors 10 are held in the recesses 311, respectively.

As illustrated in FIG. 16, in the multilayer ceramic capacitor 10 in the recess 311 of the carrier tape 310, the first main surface M1 of the ceramic body 11 facing upward in the Z-axis direction faces the top tape 320. The second main surface M2 of the ceramic body 11 facing downward in the Z-axis direction faces the bottom surface of the recess 311.

When the multilayer ceramic capacitor 10 packaged as the package 300 is mounted, the top tape 320 is peeled off from the sealing surface P of the carrier tape 310 along the Y-axis direction. This allows the recesses 311 in which the multilayer ceramic capacitors 10 are accommodated to be sequentially opened upward in the Z-axis direction in the package 300.

The multilayer ceramic capacitor 10 accommodated in the opened recess 311 is taken out while the first main surface M of the ceramic body 11 facing upward in the Z-axis direction is sucked by the tip of the suction nozzle of a mounting device. Next, the mounting device moves the suction nozzle to move the multilayer ceramic capacitor 10 onto the mounting surface G of the mounting substrate 210.

The mounting device causes the second main surface M2 of the ceramic body 11 to face the mounting surface G and aligns the external electrodes 14 and 15 with the pair of connection electrodes 212 to which solder paste is applied, and then releases the suction of the first main surface M1 of the ceramic body 11 by the suction nozzle. As a result, the multilayer ceramic capacitor 10 is mounted on the mounting surface G.

Then, the solder paste is melted and then hardened by putting the mounting substrate 210 with the mounting surface G on which the multilayer ceramic capacitor 10 is placed in a reflow furnace or the like. As a result, the external electrodes 14 and 15 of the multilayer ceramic capacitor 10 are connected to the pair of connection electrodes 212 of the mounting substrate 210 through the solder H, whereby the circuit board 200 illustrated in FIG. 14 is obtained.

### Second Embodiment

The multilayer ceramic capacitor 10 according to a second embodiment is different from the multilayer ceramic capacitor 10 of the first embodiment only in the configuration of the internal electrodes 12 and 13, and has the same appearance as the multilayer ceramic capacitor 10 of the first embodiment illustrated in FIG. 1. In the present embodiment, the same or corresponding components as those in the first embodiment are denoted by the same reference numerals, and detailed description thereof will be omitted.

### [Structure of Multilayer Ceramic Capacitor 10]

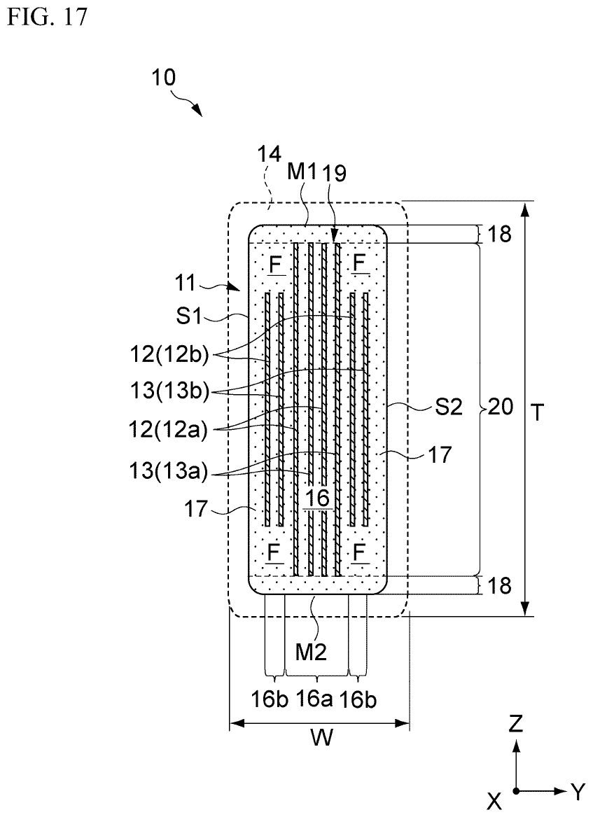

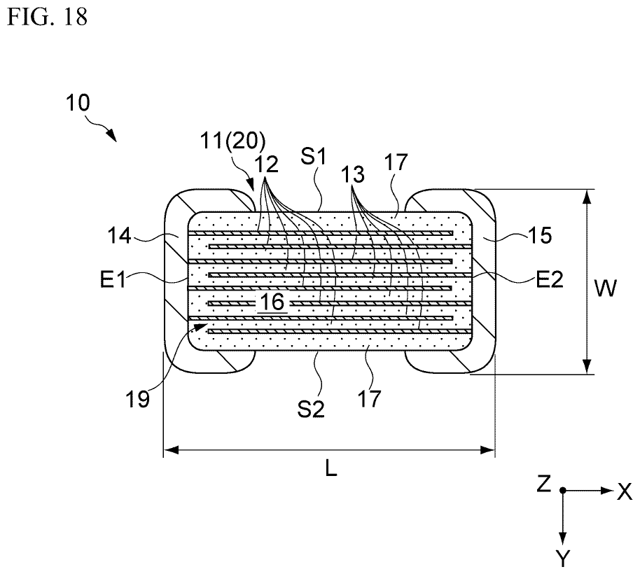

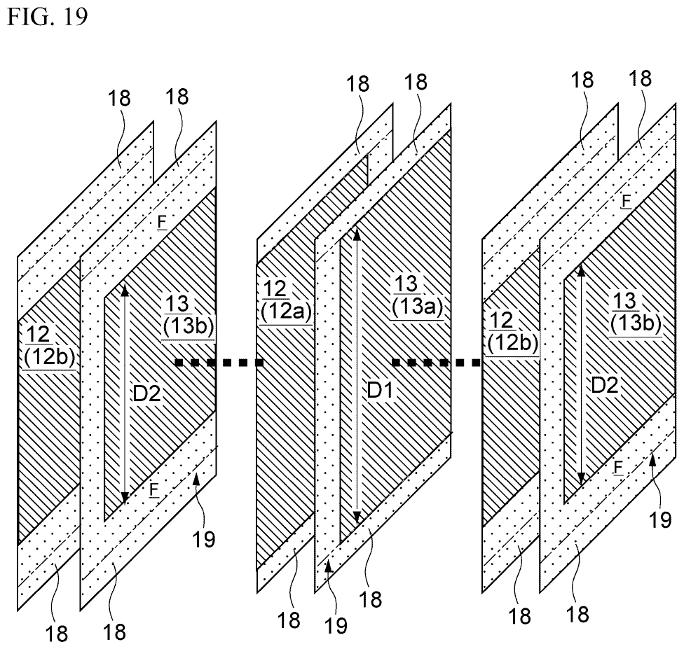

FIG. 17 to FIG. 19 illustrate the multilayer ceramic capacitor 10 according to the second embodiment. FIG. 17 is a vertical cross-sectional view of the multilayer ceramic capacitor 10 taken along line B-B′ in FIG. 1. FIG. 18 is a horizontal cross-sectional view of the multilayer ceramic capacitor 10 taken along line D-D′ in FIG. 1. FIG. 19 is a partially exploded view illustrating the ceramic body 11 of the multilayer ceramic capacitor 10 for each ceramic layer 19. FIG. 19 also illustrates the margin portions 18 adjacent to the ceramic layer 19.

In the capacitance formation portion 16 according to the first embodiment, the stacking direction of the internal electrodes 12 and 13 is parallel to the Z-axis, and the width direction of the internal electrodes 12 and 13 is parallel to the Y-axis. In contrast, in the capacitance formation portion 16 according to the present embodiment, the stacking direction is a direction parallel to the Y-axis, the lead-out direction of the internal electrodes 12 and 13 is a direction parallel to the X-axis, and the width direction of the internal electrodes 12 and 13 is a direction parallel to the Z-axis.

The internal electrodes 12 and 13 of the capacitance formation portion 16 are configured in a sheet shape extending along the X-Z plane, and are alternately stacked with the ceramic layers 19 in the Y-axis direction. In the present embodiment, the pair of cover portions 17 cover the capacitance formation portion 16 from the Y-axis direction.

In the present embodiment, the margin portions 18 are formed along the Y-axis direction and cover the multilayer portion 20 from the Z-axis direction. The margin portion 18 contains an additive element composed of at least one of the following elements: Mg, Mn, Zr, Ti, Li, Mo, Nb, Cu, a rare earth element, and Sn at a higher concentration than the multilayer portion 20, as in the first embodiment.

As illustrated in FIG. 17 and FIG. 19, the first and second internal electrodes 12 and 13 include the first and second inner-side internal electrodes 12a and 13a located in the inner side in the Y-axis direction and the first and second outer-side internal electrodes 12b and 13b located in both outer sides in the Y-axis direction. Accordingly, the capacitance formation portion 16 of the present embodiment is divided into the inner-side portion 16a, which is located in the inner side in the Y-axis direction, and a pair of the outer-side portions 16b, which are located in both outer sides in the Y-axis direction. The inner-side internal electrodes 12a and 13a are stacked in the inner-side portion 16a, and the outer-side internal electrodes 12b and 13b are stacked in each of the outer-side portions 16b.

As illustrated in FIG. 19, the outer-side internal electrodes 12b and 13b have the maximum width dimension D2 smaller than the minimum width dimension D1 of the inner-side internal electrodes 12a and 13a. Thus, as illustrated in FIG. 17, the capacitance formation portion 16 includes the electrode absence sections F disposed between the end portions 12e in the Z-axis direction of the outer-side internal electrodes 12b and the margin portions 18 and between the end portions 13e in the Z-axis direction of the outer-side internal electrodes 13b and the margin portions 18. Thus, even when the margin portions 18 shrink in the Y-axis direction during firing, the end portions 12e and 13e of the outer-side internal electrodes 12b and 13b are less likely to be curved in the Y-axis direction, and thus, poor insulation in the outer-side internal electrodes 12b and 13b can be suppressed.

In addition, in the present embodiment, since the stacking direction is parallel to the Y-axis, the total number of stacked internal electrodes 12 and 13 is smaller than that in the first embodiment in which the stacking direction is parallel to the Z-axis. On the other hand, since each of the internal electrodes 12 and 13 extends along the X-Z plane, the area of each of the internal electrodes 12 and 13 can be made larger than that in the first embodiment. This makes it possible to sufficiently ensure the electrostatic capacitance of the multilayer ceramic capacitor 10.

In the present embodiment, the width direction of the internal electrodes 12 and 13 is parallel to the Z-axis, and therefore the maximum width dimension D2 of the outer-side internal electrodes 12b and 13b can be made larger than that in the first embodiment. Therefore, the width dimension and area of the end portion of each of the outer-side internal electrodes 12b on the end surface E1 and the width dimension and area of the end portion of each of the outer-side internal electrodes 13b on the end surface E2 can be sufficiently ensured. Thus, in the present embodiment, even when the maximum width dimension D2 of the outer-side internal electrodes 12b and 13b is smaller than the minimum width dimension D1 of the inner-side internal electrodes 12a and 13a, poor connection between the outer-side internal electrodes 12b and the external electrode 14 and between the outer-side internal electrodes 13b and the external electrode 15 is inhibited. As a result, according to the present embodiment, a decrease in the electrostatic capacitance of the multilayer ceramic capacitor 10 due to such poor connection can be significantly reduced or prevented.

### [Method of Manufacturing Multilayer Ceramic Capacitor 10]

A method of manufacturing the multilayer ceramic capacitor 10 according to the present embodiment will be described below. The method of manufacturing the multilayer ceramic capacitor 10 according to the present embodiment is performed in accordance with the flowchart illustrated in FIG. 6. However, in the manufacturing method of the present embodiment, the planar shape of the conductor pattern, the number of stacked ceramic sheets, and the like are different from those of the first embodiment.

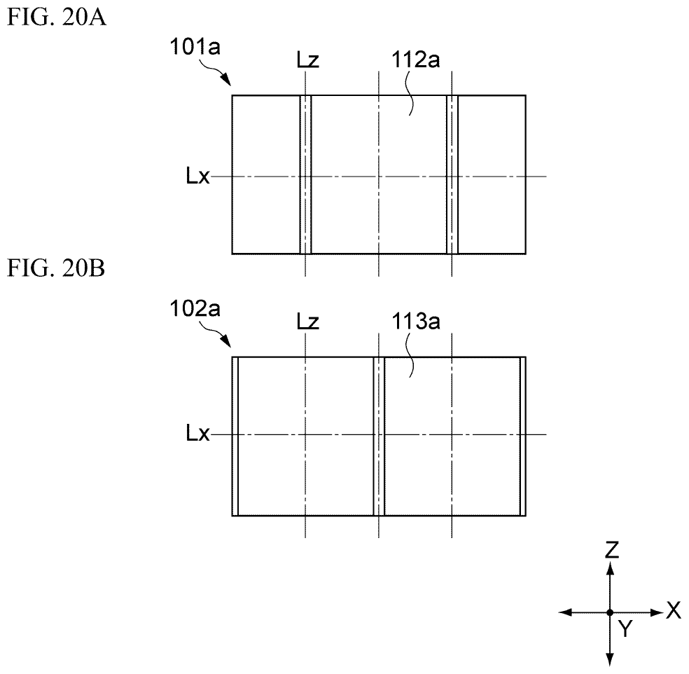

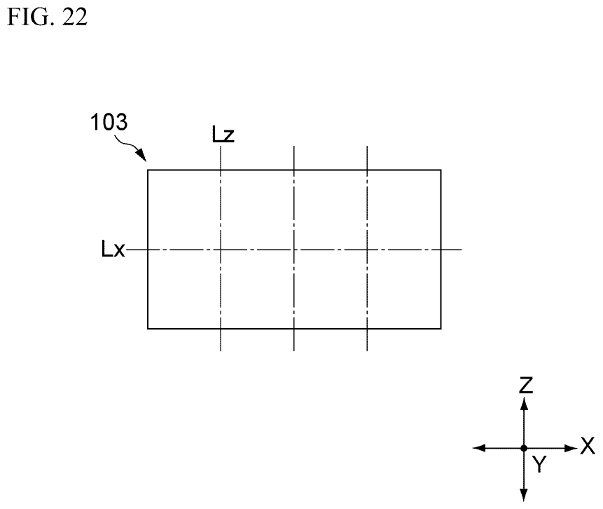

In step S01, as illustrated in FIG. 20A to FIG. 22, prepared are the first and second inner-side ceramic sheets 101a and 102a for forming the inner-side portion 16a of the capacitance formation portion 16, the first and second outer-side ceramic sheets 101b and 102b for forming a pair of the outer-side portions 16b of the capacitance formation portion 16, and the cover ceramic sheets 103 for forming the cover portions 17.

As illustrated in FIG. 20A to FIG. 22, the ceramic sheets 101a, 102a, 101b, 102b, and 103 according to the present embodiment extend along the X-Z plane, not the X-Y plane. Therefore, the ceramic sheets 101a, 102a, 101b, 102b, and 103 according to the present embodiment have a configuration in which the shape of each ceramic sheet illustrated in FIG. 7A to FIG. 9 is entirely stretched in the Y-axis direction, and the Y-axis in FIG. 7A to FIG. 9 is changed to the Z-axis. The cutting lines for separating the multilayer ceramic capacitors 10 into individual pieces include the first cutting lines Lx parallel to the X-axis and the second cutting lines Lz parallel to the Z-axis.

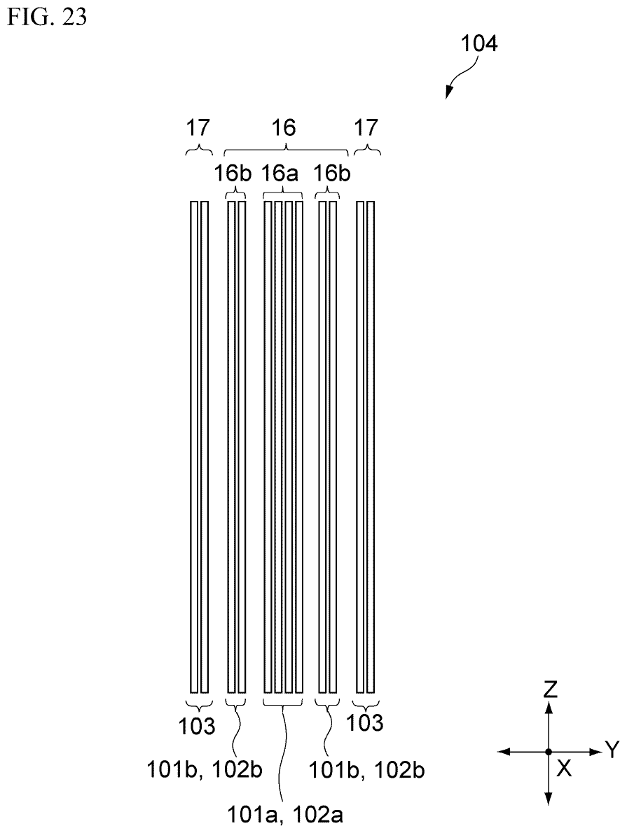

Then, in step S02, as illustrated in FIG. 23, the ceramic sheets 101a, 102a, 101b, 102b, and 103 are stacked and pressure-bonded in the Y-axis direction to produce the multilayer sheet 104. The number of stacked ceramic sheets 101a, 102a, 101b, 102b, and 103 is appropriately set in accordance with the dimension of the ceramic body 11 in the Y-axis direction, and is typically set to be smaller than that in the first embodiment.

Then, in step S03, the multilayer sheet 104 obtained in step S02 is cut along the cut lines Lx and Lz, thereby obtaining unfired multilayer chips 120.

Then, in step S04, the unfired margin portions 118 are formed on the respective cut surfaces 120s of the multilayer chip 120 obtained in step S03, the cut surfaces 120s being substantially perpendicular to the Z-axis. Through the above process, the unfired ceramic body 11 is produced.

Then, the same step S05 (firing) as in the first embodiment is performed, and the external electrodes 14 and 15 are formed on respective end portions of the ceramic body 11 in the X-axis direction in the same step S06 (forming of external electrodes) as in the first embodiment, whereby the multilayer ceramic capacitor 10 illustrated in FIG. 17 to FIG. 19 is produced.

Here, in the ceramic body 11 of the present embodiment, since the stacking direction is parallel to the Y-axis, as described below, the main surfaces M1 and M2 can have a higher flatness than the side surfaces S1 and S2.

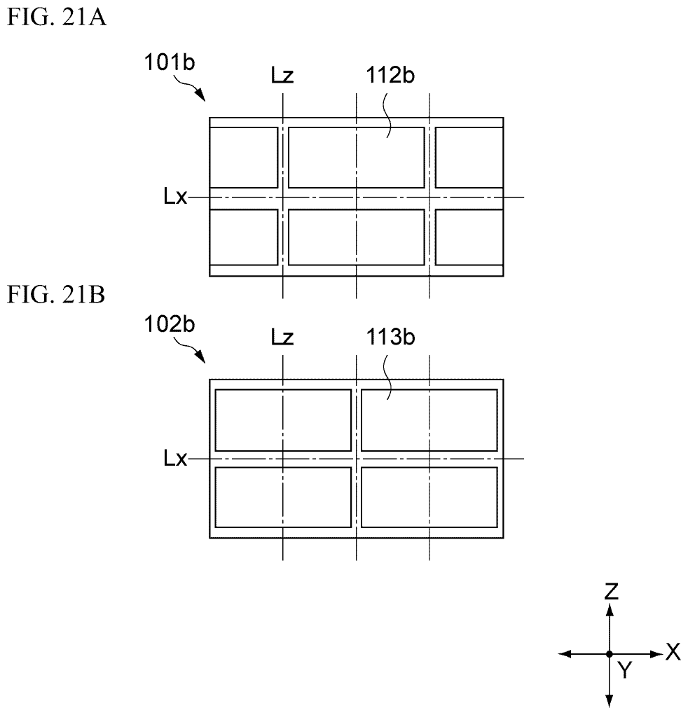

The side surfaces S1 and S2 are formed of surfaces substantially perpendicular to the Y-axis of the multilayer sheet 104. As illustrated in FIG. 20A, FIG. 20B, FIG. 21A, and FIG. 21B, the ceramic sheets 101a, 102a, 101b, and 102b have regions where the conductor patterns 112a, 112b, 113a, and 113b are not formed. Therefore, steps and undulations due to the thicknesses of the conductor patterns 112a, 112b, 113a, and 113b are likely to be formed on the surface substantially perpendicular to the Y-axis of the multilayer sheet 104, which is formed by stacking these ceramic sheets. That is, the flatness of the side surfaces S1 and S2 is likely to be low.

On the other hand, the main surfaces M1 and M2 are formed of the margin portions 18. In the present embodiment, the margin portions 18 are formed by attaching the ceramic sheets 118s to the cut surfaces 120s substantially perpendicular to the Z-axis of the multilayer chip 120. Since steps or undulations are not easily formed on the cut surface 120s or the ceramic sheet 118s, the main surfaces M1 and M2 can have higher flatness than the side surfaces S1 and S2.

As illustrated in FIG. 14, the main surfaces M1 and M2 face the mounting substrate 210 when the multilayer ceramic capacitor 10 is mounted on the mounting substrate 210. The high flatness of the main surfaces M1 and M2 can stabilize the posture of the multilayer ceramic capacitor 10 on the mounting substrate 210. Thus, the multilayer ceramic capacitor 10 is inhibited from tilting on the mounting substrate 210 while having a high center of gravity and a high height. By inhibiting the tilt of the multilayer ceramic capacitor 10, contact between the multilayer ceramic capacitor 10 and an adjacent electronic component is inhibited, and thus, it is possible to inhibit a defect such as a short circuit.

Furthermore, since the main surfaces M1 and M2 have high flatness, as illustrated in FIG. 16, the multilayer ceramic capacitor 10 can be easily sucked, from the package 300 including the multilayer ceramic capacitor 10, by a chip mounter for mounting.

If the first main surface M1 has a step or undulation, it is difficult for the suction nozzle of the chip mounter to stably suck the first main surface M1. In the present embodiment, the main surfaces M1 and M2 have high flatness, and thus the suction nozzle can stably suck the first main surface M1. Therefore, the multilayer ceramic capacitor 10 can effectively inhibit suction defects during mounting.

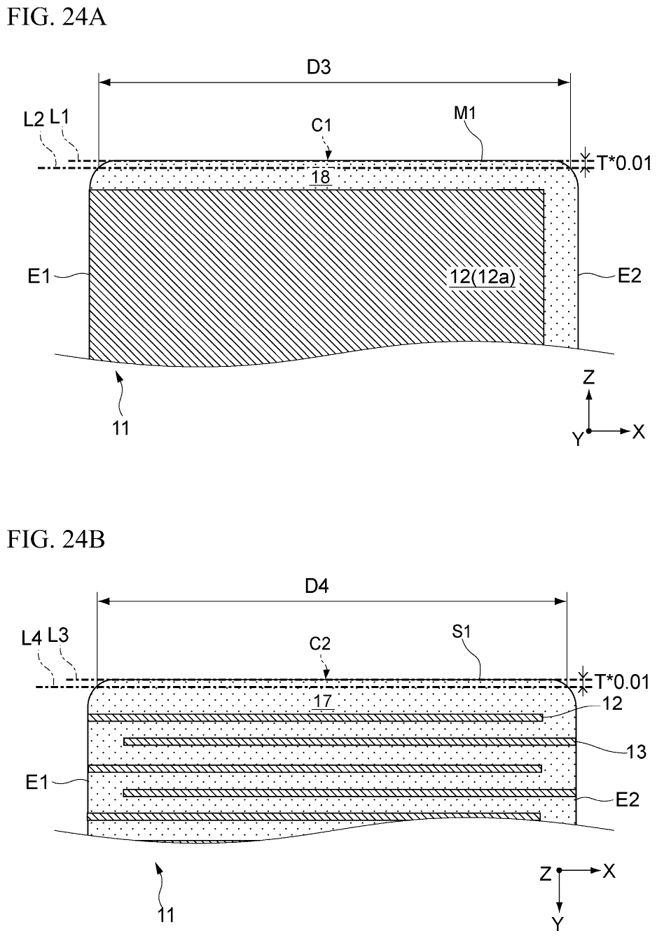

The flatness of each surface can be compared as follows. The cross-sectional view of FIG. 24A illustrates an example in which the first main surface M1 is the measurement target surface. The cross-sectional view of FIG. 24B illustrates an example in which the first side surface S1 is the measurement target surface.

First, as illustrated in FIG. 24A, a cross section perpendicular to the first main surface M1 and parallel to an X-Z plane that bisects the first main surface M1 is exposed. In this cross section, a first imaginary line L1, which passes through the center point C1 in the X-axis direction of the first main surface M1 and is parallel to the X-axis direction, and a second imaginary line L2, which is parallel to the first imaginary line L1 and is separated from the first imaginary line L1 by an interval of 1% of the dimension T in the Z-axis direction of the ceramic body 11 (T*0.01) are defined. Then, the distance between two points where the second virtual line L2 and the first main surface M1 intersect is measured as a dimension D3 of the flat region of the first main surface M1. The dimension D3 on the second main surface M2 is also measured in the same manner.

As illustrated in FIG. 24B, a cross section perpendicular to the first side surface S1 and parallel to an X-Y plane that bisects the first side surface S1 is exposed. In this cross section, a third imaginary line L3, which passes through the center point C2 in the X-axis direction of the first side surface S1 and is parallel to the X-axis direction, and a fourth imaginary line L4, which is parallel to the third imaginary line L3 and is separated from the third imaginary line L3 by an interval of 1% of the dimension T in the Z-axis direction of the ceramic body 11 (T*0.01) are defined. Then, the distance between two points where the fourth virtual line L4 and the first side surface S1 intersect is measured as a dimension D4 of the flat region of the first side surface S1. The dimension D4 on the second side surface S2 is also measured in the same manner.

Then, for five or more multilayer ceramic capacitors 10, the average value of the dimensions D3 of the main surfaces M1 and M2 and the average value of the dimensions D4 of the side surfaces S1 and S2 are calculated. The calculated average value of the dimension D3 and the calculated average value of the dimension D4 are compared, and when the average value of the dimension D3 is larger than the average value of the dimension D4, it can be determined that the main surfaces M1 and M2 have higher flatness than the side surfaces S1 and S2.

Furthermore, the multilayer ceramic capacitor 10 according to the present embodiment can effectively suppress sound emission in the circuit board 200, as described below.

In the multilayer ceramic capacitor 10 according to the present embodiment, the stacking direction of the internal electrodes 12 and 13 is the in-plane direction of the base material 211, and thus vibration due to the electrostriction of the ceramic body 11 is less likely to be generated in the base material 211. In addition, the ceramic body 11 of the present embodiment has the electrode absence sections F as in the first embodiment, and the number of stacked internal electrodes 12 and 13 can be reduced. Therefore, in the present embodiment, the amount of deformation due to electrostriction in the ceramic body 11 can be further reduced, and sound emission in the circuit board 200 can be further effectively inhibited.

### EXAMPLES

As Example 1 of the present disclosure, a sample of the multilayer ceramic capacitor 10 according to the first embodiment described above was fabricated. In addition, as Example 2 of the present disclosure, a sample of the multilayer ceramic capacitor 10 according to the second embodiment was fabricated. As Comparative Example of the present disclosure, a sample of the multilayer ceramic capacitor 10A illustrated in FIG. 5 was fabricated. One hundred samples were prepared for each of Examples 1 and 2 and Comparative Example.

As Example 3 of the present disclosure, a sample of the multilayer ceramic capacitor 10 according to the first embodiment described above was fabricated. In addition, as Example 4 of the present disclosure, a sample of the multilayer ceramic capacitor 10 according to the second embodiment described above was fabricated. One hundred samples were prepared for each of Examples 3 and 4.

In each of the samples of Examples 1 and 2 and Comparative Example, the dimension L in the X-axis direction was 0.6 mm, the dimension W in the Y-axis direction was 0.3 mm, and the dimension T in the Z-axis direction was 0.5 mm. In each of the samples of Examples 1 and 2 and Comparative Example, the thickness of each cover portion 17 was 25 μm, the thickness of each margin portion 18 was 20 μm, and the thickness of each of the internal electrodes 12 and 13 and the thickness of each ceramic layer 19 were 0.5 μm.

In each of the samples of Examples 3 and 4, the dimension L in the X-axis direction was 0.6 mm, the dimension W in the Y-axis direction was 0.3 mm, and the dimension T in the Z-axis direction was 0.4 mm. In each of the samples of Examples 3 and 4, the thickness of each cover portion 17 was 25 μm, the thickness of each margin portion 18 was 20 μm, and the thickness of each of the internal electrodes 12 and 13 and the thickness of each ceramic layer 19 was 0.5 μm.

In the samples of Example 1, the minimum width dimension D1 of each of the inner-side internal electrodes 12a and 13a was 260 μm, and the maximum width dimension D2 of each of the outer-side internal electrodes 12b and 13b was 200 μm. In the samples of Example 1, the total number of stacked internal electrodes 12 and 13 was 450. The number of the outer-side internal electrodes 12b and 13b stacked in each outer-side portion 13b was 50, and the number of the inner-side internal electrodes 12a and 13a stacked in the inner-side portion 16a was 350.

In the samples of Example 2, the minimum width dimension D1 of each of the inner-side internal electrodes 12a and 13a was 460 μm, and the maximum width dimension D2 of each of the outer-side internal electrodes 12b and 13b was 400 am. In the samples of Example 2, the total number of stacked internal electrodes 12 and 13 was 250. The number of the outer-side internal electrodes 12b and 13b stacked in each outer-side portion 16b was 50, and the number of the inner-side internal electrodes 12a and 13a stacked in the inner-side portion 16a was 150.

In the samples of Comparative Example, the width dimension of all the internal electrodes 12 and 13 was 260 μm, and the total number of stacked internal electrodes 12 and 13 was 450.

In the samples of Example 3, the minimum width dimension D1 of each of the inner-side internal electrodes 12a and 13a was 260 μm, and the maximum width dimension D2 of each of the outer-side internal electrodes 12b and 13b was 200 μm. In the samples of Example 3, the total number of stacked internal electrodes 12 and 13 was 350. The number of the outer-side internal electrodes 12b and 13b stacked in each outer-side portion 16b was 50, and the number of the inner-side internal electrodes 12a and 13a stacked in the inner-side portion 16a was 250.

In the samples of Example 4, the minimum width dimension D1 of each of the inner-side internal electrodes 12a and 13a was 360 μm, and the maximum width dimension D2 of each of the outer-side internal electrodes 12b and 13b was 300 μm. In the samples of Example 4, the total number of stacked internal electrodes 12 and 13 was 250. The number of the outer-side internal electrodes 12b and 13b stacked in each outer-side portion 16b was 50, and the number of the inner-side internal electrodes 12a and 13a stacked in the inner-side portion 16a was 150.

In the samples of each of Examples 1 and 2 and Comparative Example, one of the following elements: Mg, Mn, Zr, rare earth elements (Y, Dy, Ho), and Sn was added to the ceramic sheets 118s forming the margin portions 18 so that the ceramic sheets 118s have a higher concentration of the additive element than the ceramic sheets forming the multilayer portion 20 (multilayer sheet 104).

In the samples of each of Examples 3 and 4, one of the following elements: Mg, Mn, Zr, rare earth elements (Y, Dy, Ho), and Sn was added to the ceramic sheets 118s forming the margin portions 18 so that the ceramic sheets 118s have a higher concentration of the additive element than the ceramic sheets forming the multilayer portion 20 (multilayer sheet 104).

The samples of each of Examples 1 and 2 and Comparative Example were subjected to a reliability test in which a direct current voltage of 10 V was applied under an environment of 105° C. Some of the samples of Comparative Example reached dielectric breakdown in less than 500 hours, but no sample of Examples 1 and 2 reached dielectric breakdown in less than 500 hours. Thus, it was found that the samples of Examples 1 and 2 were able to suppress poor insulation more than the samples of Comparative Example.

The samples of Examples 3 and 4 were subjected to a reliability test in which a direct current voltage of 10 V was applied in an environment of 105° C. In the samples of Examples 3 and 4, no sample reached dielectric breakdown in less than 500 hours. Thus, it was found that the samples of Examples 3 and 4 were able to suppress poor insulation more than the samples of Comparative Examples.

Furthermore, the electrostatic capacitance was measured under the conditions of 1 kHz and 0.5 Vrms for 100 samples of each of Examples 1 and 2. Then, for each of Examples 1 and 2, the largest value and the smallest value with respect to the average value of the electrostatic capacitance were calculated, and it was confirmed whether the largest value and the smallest value were within a range of 55% or +10% centered on the average value. In Example 2, the largest value and the smallest value of the electrostatic capacitance were within a range of +5% centered on the average value. On the other hand, in Example 1, the largest value and the smallest value of the electrostatic capacitance fell within a range of +10% centered on the average value, but did not fall within a range of 55% centered on the average value.

This result reveals that the samples of Example 2 can suppress the variation in electrostatic capacitance more than the samples of Example 1. The reason for this is presumed to be that poor connection between the external electrode 14 and the internal electrodes 12 and between the external electrode 15 and the internal electrodes 13 is suppressed in the samples of Example 2.

Further, the electrostatic capacitance was measured under the conditions of 1 kHz and 0.5 Vrms for 100 samples of each of Examples 3 and 4. Then, for each of Examples 3 and 4, the largest value and the smallest value with respect to the average value of the electrostatic capacitance were calculated, and it was confirmed whether the largest value and the smallest value fell within a range of 55% or +10% centered on the average value. In Example 4, the largest value and the smallest value of the electrostatic capacitance were within a range of +5% centered on the average value. On the other hand, in Example 3, the largest value and the smallest value of the electrostatic capacitance fell within a range of 10% centered on the average value, but did not fall within a range of 55% centered on the average value.

This result reveals that the samples of Example 4 can suppress the variation in electrostatic capacitance more than the samples of Example 3. The reason for this is presumed to be that in the samples of Example 4, poor connection between the external electrode 14 and the internal electrodes 12 and between the external electrode 15 and the internal electrodes 13 is suppressed.

Factors that greatly affect the occurrence of poor connection between the external electrode 14 and the internal electrodes 12 and between the external electrode 15 and the internal electrodes 13 include the areas of the internal electrodes 12 and 13 exposed on the end surfaces E1 and E2, respectively. For example, the outer-side internal electrodes 12b and 13b of Example 2 have a thickness of 0.5 μm and a width dimension of 400 μm, and the area obtained by multiplying these values is 200 μm². The inner-side internal electrodes 12a and 13a of Example 2 have a thickness of 0.5 μm and a width dimension of 460 μm, and the area obtained by multiplying these values is 230 μm².

On the other hand, the outer-side internal electrodes 12b and 13b of Example 1 have a thickness of 0.5 μm and a width dimension of 200 am, and therefore, the area obtained by multiplying these values is 100 μm². The inner-side internal electrodes 12a and 13a of Example 1 have a thickness of 0.5 μm and a width dimension of 260 μm, and the area obtained by multiplying these values is 130 μm².

The outer-side internal electrodes 12b and 13b of Example 4 have a thickness of 0.5 μm and a width dimension of 300 μm, and the area obtained by multiplying these values is 150 μm². The inner-side internal electrodes 12a and 13a of Example 4 have a thickness of 0.5 μm and a width dimension of 360 μm, and the area obtained by multiplying these values is 180 μm².

On the other hand, the outer-side internal electrodes 12b and 13b of Example 3 have a thickness of 0.5 μm and a width dimension of 200 μm, and the area obtained by multiplying these values is 100 μm². The inner-side internal electrodes 12a and 13a of Example 3 have a thickness of 0.5 μm and a width dimension of 260 μm, and the area obtained by multiplying these values is 130 μm².

As described above, in the samples of Example 2, the areas of the internal electrodes 12 and 13 exposed on the end surfaces E1 and E2 are increased by 1.7 times or more from those of the samples of Example 1, and the internal electrodes 12 and 13 are likely to be stably connected to the external electrodes 14 and 15. As a result, it is presumed that the variation in electrostatic capacitance was suppressed in the samples of Example 2 as compared with the samples of Example 1.

Similarly, in the samples of Example 4, the areas of the internal electrodes 12 and 13 exposed on the end surfaces E1 and E2 are increased by 1.3 times or more from those of the samples of Example 3, and the internal electrodes 12 and 13 are likely to be stably connected to the external electrodes 14 and 15. As a result, it is presumed that the variation in electrostatic capacitance was suppressed in the samples of Example 4 as compared with the samples of Example 3.

### Other Embodiments

Although the embodiments of the present invention have been described above, the present invention is not limited to the above-described embodiments, and various modifications can be made.

For example, the shapes of the internal electrodes 12 and 13 are not limited to rectangles, and can be changed within a range in which the effect of the present disclosure is exhibited. For example, the internal electrodes 12 and 13 may include an electrode body portion located in the opposing section and lead-out portions extending from the electrode body portion toward the end surfaces E1 and E2, respectively, and the width dimension of the lead-out portion may be smaller than the width dimension of the electrode body portion. Even in this case, the maximum width dimension D2 of each of the outer-side internal electrodes 12b and 13b is configured to be smaller than the minimum width dimension D1 of each of the inner-side internal electrodes 12a and 13a.

Furthermore, in the multilayer ceramic capacitor 10, the first main surface M1 and the second main surface M2 of the ceramic body 11 may be reversed. That is, in the circuit board 200 illustrated in FIG. 14 and the ceramic body 11 of the multilayer ceramic capacitor 10 in the package 300 illustrated in FIG. 16, the first main surface M1 may face downward in the Z-axis direction and the second main surface M2 may face upward in the Z-axis direction.

What is claimed is:

1. A multilayer ceramic capacitor that has a dimension in a first direction along a first axis equal to or greater than 1.5 times a dimension in a second direction along a second axis orthogonal to the first axis, and is to be mounted on a mounting surface perpendicular to the first axis, the multilayer ceramic capacitor comprising:
a ceramic body having a pair of main surfaces perpendicular to the first axis, a pair of side surfaces perpendicular to the second axis, and a pair of end surfaces perpendicular to a third axis orthogonal to the first axis and the second axis; and
a pair of external electrodes covering the pair of end surfaces, respectively,
wherein the ceramic body further includes:
a multilayer portion including a plurality of internal electrodes that are alternately stacked with ceramic layers along a stacking direction parallel to the first axis or the second axis and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis,
wherein the plurality of internal electrodes includes:
a plurality of inner-side internal electrodes located in an inner side in the stacking direction, and
a plurality of outer-side internal electrodes that are located in both outer sides in the stacking direction and have a maximum width dimension smaller than a minimum width dimension of the inner-side internal electrodes.

2. The multilayer ceramic capacitor according to claim 1, wherein the maximum width dimension of the outer-side internal electrodes is equal to or greater than two times a thickness dimension of each of the margin portions.

3. The multilayer ceramic capacitor according to claim 1, wherein the maximum width dimension of the outer-side internal electrodes is equal to or less than 10 times a thickness dimension of each of the margin portions.

4. The multilayer ceramic capacitor according to claim 1, wherein respective distances in the width direction between the margin portions and end portions in the width direction of the outer-side internal electrodes are equal to or greater than a thickness dimension of each of the margin portions.

5. The multilayer ceramic capacitor according to claim 1, wherein respective distances in the width direction between the margin portions and end portions in the width direction of the outer-side internal electrodes are equal to or less than five times a thickness dimension of each of the margin portions.

6. The multilayer ceramic capacitor according to claim 1, wherein the number of the outer-side internal electrodes stacked in one side in the stacking direction is equal to or greater than 5% of and equal to or less than 25% of the number of all the internal electrodes.

7. The multilayer ceramic capacitor according to claim 1,
wherein the stacking direction is parallel to the second axis, and
wherein the width direction of the internal electrodes is parallel to the first axis.

8. The multilayer ceramic capacitor according to claim 7, wherein the main surfaces have a higher flatness than the side surfaces.

9. A package comprising:
the multilayer ceramic capacitor according to claim 1;
a carrier tape having a sealing surface and a recess, the sealing surface being perpendicular to the first axis, the recess being recessed from the sealing surface in the first direction and accommodating the multilayer ceramic capacitor; and
a top tape that is attached to the sealing surface and covers the recess.

10. A circuit board comprising:
the multilayer ceramic capacitor according to claim 1; and
a mounting substrate having the mounting surface and a pair of connection electrodes, the pair of connection electrodes being provided on the mounting surface and connected to the pair of external electrodes of the multilayer ceramic capacitor through solder.

11. A multilayer ceramic capacitor that has a dimension in a first direction along a first axis equal to or greater than 1.3 times a dimension in a second direction along a second axis orthogonal to the first axis, and is to be mounted on a mounting surface perpendicular to the first axis, the multilayer ceramic capacitor comprising:
a ceramic body having a pair of main surfaces perpendicular to the first axis, a pair of side surfaces perpendicular to the second axis, and a pair of end surfaces perpendicular to a third axis orthogonal to the first axis and the second axis; and
a pair of external electrodes covering the pair of end surfaces, respectively,
wherein the ceramic body further includes:
a multilayer portion including a plurality of internal electrodes that are alternately stacked with ceramic layers along a stacking direction parallel to the first axis or the second axis and are led out to the end surfaces, and
a pair of margin portions that are formed along the stacking direction, cover the multilayer portion from a width direction of the internal electrodes, and contain an additive element composed of at least one of the following elements: Mg, Mn, Zr, Ti, Li, Mo, Nb, Cu, a rare earth element, and Sn at a higher concentration than the multilayer portion, the width direction being orthogonal to the stacking direction and the third axis,
wherein the plurality of internal electrodes includes:
a plurality of inner-side internal electrodes located in an inner side in the stacking direction, and
a plurality of outer-side internal electrodes that are located in both outer sides in the stacking direction and have a maximum width dimension smaller than a minimum width dimension of the inner-side internal electrodes.

12. The multilayer ceramic capacitor according to claim 11, wherein the maximum width dimension of the outer-side internal electrodes is equal to or greater than two times a thickness dimension of each of the margin portions.

13. The multilayer ceramic capacitor according to claim 11, wherein the maximum width dimension of the outer-side internal electrodes is equal to or less than 10 times a thickness dimension of each of the margin portions.

14. The multilayer ceramic capacitor according to claim 11, wherein respective distances in the width direction between the margin portions and end portions in the width direction of the outer-side internal electrodes are equal to or greater than a thickness dimension of each of the margin portions.

15. The multilayer ceramic capacitor according to claim 11, wherein respective distances in the width direction between the margin portions and end portions in the width direction of the outer-side internal electrodes are equal to or less than five times a thickness dimension of the margin portion.

16. The multilayer ceramic capacitor according to claim 11, wherein the number of the outer-side internal electrodes stacked in one side in the stacking direction is equal to or greater than 5% of and equal to or less than 25% of the number of all the internal electrodes.

17. The multilayer ceramic capacitor according to claim 11,
wherein the stacking direction is parallel to the second axis, and
wherein the width direction of the internal electrode is parallel to the first axis.

18. The multilayer ceramic capacitor according to claim 17, wherein the main surfaces have a higher flatness than the side surfaces.

19. A package comprising:
the multilayer ceramic capacitor according to claim 11;
a carrier tape having a sealing surface and a recess, the sealing surface being perpendicular to the first axis, the recess being recessed from the sealing surface in the first direction and accommodating the multilayer ceramic capacitor; and
a top tape that is attached to the sealing surface and covers the recess.

20. A circuit board comprising:
the multilayer ceramic capacitor according to claim 11; and
a mounting substrate having the mounting surface and a pair of connection electrodes, the pair of connection electrodes being provided on the mounting surface and connected to the pair of external electrodes of the multilayer ceramic capacitor through solder.
